(19) United States
(12) Patent Application Publication
(10) Pub. No.: US 2026/0018443 A1
(43) Pub. Date: Jan. 15, 2026

(54) SUBSTRATE STORAGE RACKS FOR SEMICONDUCTOR PROCESSING SYSTEMS

(71) Applicant: ASM IP Holding B.V., Almere (NL)

(72) Inventors: Nayna Khosla, Tempe, AZ (US); Amir Kajbafvala, Chandler, AZ (US); Kyle Tantiwong, Scottsdale, AZ (US)

(21) Appl. No.: 19/335,633

(22) Filed: Sep. 22, 2025

Related U.S. Application Data
(63) Continuation-in-part of application No. 17/980,100, filed on Nov. 3, 2022.
(60) Provisional application No. 63/276,918, filed on Nov. 8, 2021.

(51) Int. Cl. H01L 21/673; H01L 21/677

(52) U.S. Cl. CPC H01L 21/67323; H01L 21/67769; H01L 21/67778

(57) ABSTRACT

A substrate storage rack for a semiconductor processing system may include a bottom plate, a top plate, and/or at least one column assembly. The top plate may be spaced apart from the bottom plate, and the column assembly may connect the top plate to the bottom plate. The column assembly may have multiple protrusion elements. Each protrusion element may have a top surface opening that supports a ball member. Each ball member in the column assembly may protrude upward from its respective protrusion element toward the top plate and may be configured to support a substrate within the rack. Semiconductor processing systems and methods of making substrate storage racks are also described.

### CROSS-REFERENCE TO RELATED APPLICATIONS

This application is a continuation-in-part of U.S. patent application Ser. No. 17/980,100 filed Nov. 3, 2022, titled “SUBSTRATE STORAGE RACKS FOR SEMICONDUCTOR PROCESSING SYSTEMS,” which claims priority to U.S. Provisional Patent Application Ser. No. 63/276,918 filed Nov. 8, 2021 titled “SUBSTRATE STORAGE RACKS FOR SEMICONDUCTOR PROCESSING SYSTEMS,” each of which is hereby incorporated by reference in its entirety.

### FIELD

The present disclosure generally relates to fabricating semiconductor devices, and more particularly, to storing substrates during the fabrication of semiconductor devices, such as within semiconductor processing systems employed to deposit films onto substrates.

### BACKGROUND

Semiconductor processing systems may include one or more process chambers that are adapted to carry out any number of processes, such as degassing, cleaning or pre-cleaning, deposition such as chemical vapor deposition (CVD), physical vapor deposition (PVD), or atomic layer deposition (ALD), coating, oxidation, nitration, etching (e.g., plasma etch), or the like. One or more load lock chambers may be provided to enable entry and exit of substrates from a factory interface (e.g., an equipment front end module (EFEM)). Each of these process chambers and load lock chambers may be included in a cluster tool, where a plurality of process chambers may be distributed about a transfer chamber, for example. A front-end transfer robot may be housed within the factory interface to transport a substrate (e.g., a silicon wafer, glass plate, or the like) between the factory interface and the load lock chamber, and a back-end transfer robot may be housed within the transfer chamber to transport the substrate between the load lock chamber and one or more of the process modules. Transport of the substrate may be accomplished by one or more end effectors (e.g., clamps or blades) carried by the front-end transfer robot and the back-end transfer robot, and the position of the substrate within the process module may be according to a substrate centering sensor within the transfer chamber.

During processing, the front-end transfer robot may retrieve substrates from a pod and transport the substrates through the factory interface to the load lock chamber. From the load lock chamber, substrates may be transported through the transfer module by the back-end transfer robot to the process module, wherein the substrates are processed according to the requirements of the particular semiconductor device being fabricated. Once processing is complete, the substrates may be retrieved from the process module by the transfer robot and again transported through the transfer module to the load lock chamber. From the load lock chamber, the processed substrates may be transported by the front-end robot through the factory interface to a pod, and thereafter removed from the semiconductor processing system to undergo further processing.

In some semiconductor processing systems, storage racks may be provided within one or more of the factory interfaces, the load lock chamber, and the transfer chamber to store substrates before and/or after processing. The storage racks may facilitate fabrication of semiconductor devices, for example, by providing storage space within the environment of the semiconductor processing system in proximity to resources that could otherwise constrain system throughput. Such storage racks may typically include slotted rails milled from monolithic blocks of substrate-friendly materials, such as quartz or polyether ether ketone (PEEK), and suspended from backing plates for structural support. While generally acceptable for their intended purpose, the tolerances and machining time required to mill slots into such materials add complexity and cost to the manufacturing of the storage rack. The backing plates may be required to support quartz or PEEK slotted rails, which can interrupt the otherwise laminar airflow present within the internal environment of the semiconductor processing system.

Therefore, there remains a need in the art for improved substrate storage racks, semiconductor processing systems having storage racks, and methods of making storage racks for semiconductor processing systems. The present disclosure provides a solution to this need.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to substrate storage racks in semiconductor processing systems. The substrate storage racks in the present disclosure may be included in the factory interface, the load lock chamber, the pods, and/or other locations of the semiconductor processing system.

A substrate storage rack described herein may comprise a bottom plate, a top plate spaced apart from the bottom plate, at least one column assembly connecting the top plate to the bottom plate and comprising a plurality of protrusion elements, and a plurality of ball members. Each protrusion element of the plurality of protrusion elements may comprise a top surface with an opening configured to support a corresponding ball member of the plurality of ball members. The corresponding ball member of each protrusion element of the plurality of protrusion elements may protrude from the top surface of the protrusion element in a direction toward the top plate and be configured to support a substrate within the substrate storage rack.

In accordance with examples of the disclosure, the substrate, supported by one or more ball members, may be only in direct contact with the one or more ball members.

In accordance with examples of the disclosure, the opening of each protrusion element of the plurality of protrusion elements may comprise a recess on the top surface of the protrusion element.

In accordance with examples of the disclosure, the opening, of each protrusion element of the plurality of protrusion elements, comprises a recess at or near an edge of the protrusion element.

In accordance with examples of the disclosure, the ball member of each protrusion element of the plurality of protrusion elements may protrude 1 to 6 millimeters above the top surface of the protrusion element.

In accordance with examples of the disclosure, the plurality of ball members of the substrate storage rack may comprise a ceramic material. In accordance with examples of the disclosure, the plurality of ball members of the substrate storage rack may comprise silicon nitride, silicon carbide, zinc oxide, aluminum oxide, and/or quartz. In accordance with examples of the disclosure, each of the plurality of ball members may have a diameter that is from 2 to 8 millimeters. In accordance with examples of the disclosure, the plurality of protrusion elements may comprise quartz, ceramic, carbon, aluminum, stainless steel, and/or titanium. In accordance with examples of the disclosure, each protrusion element of the plurality of protrusion elements may comprise a base material comprising aluminum, and an electroless nickel plating may be disposed on at least a portion of the base material.

In accordance with examples of the disclosure, the column assembly may comprise a column portion extending longitudinally between the bottom plate and the top plate, and the plurality of protrusion elements may extend laterally from the column portion. In accordance with examples of the disclosure, the plurality of ball members may be longitudinally spaced apart along a longitudinal length of the at least one column assembly.

In accordance with examples of the disclosure, the column assembly may comprise an inner surface and an outer surface, and the plurality of protrusion elements may extend from the inner surface.

In accordance with examples of the disclosure, each protrusion element of the plurality of protrusion elements may comprise a first flat portion coupled to the inner surface and a slanted portion coupled to the first flat portion. Each protrusion element of the plurality of protrusion elements may also comprise a second flat portion coupled to the slanted portion. The second flat portion may be thinner than the first flat portion and/or may comprise the opening of the protrusion element.

In accordance with examples of the disclosure, the substrate storage rack may comprise a first column assembly, a second column assembly, and a third column assembly. In some examples of the disclosure, the first column assembly, the second column assembly, and the third column assembly may form an obtuse isosceles triangle. In some examples of the disclosure, the first column assembly, the second column assembly, and the third column assembly may form an acute isosceles triangle.

A method for storing and handling substrates in a substrate storage rack is described herein. The method may comprise providing a substrate storage rack comprising a plurality of slots for storing substrates. Each of the plurality of slots may comprise a plurality of protrusion elements and a plurality of ball members. Each protrusion element of the plurality of protrusion elements may comprise a top surface with an opening configured to support a corresponding ball member of the plurality of ball members. The method may also include storing a substrate in the substrate storage rack by disposing the substrate on top of the plurality of ball members of one of the plurality of slots.

In accordance with examples of the disclosure, the method described herein may also comprise removing the substrate from the substrate storage rack by lifting the substrate from the top of the plurality of ball members of the one of the plurality of slots.

In accordance with examples of the disclosure, during the storing of the substrate in the substrate storage rack, the substrate may be only in direct contact with the plurality of ball members of the one of the plurality of slots.

A substrate storage rack may be provided. A substrate storage rack for a semiconductor processing system may include a bottom plate, a top plate, and a column assembly. The top plate may be spaced apart from the bottom plate, the column assembly may connect the top plate to the bottom plate, and a ball member may be compressively seated within the column assembly. The ball member may protrude from the column assembly in a direction toward the top plate to support a substrate within the substrate storage rack and on the ball member.

In addition to one or more of the features described above, or as an alternative, further examples of the substrate storage rack may include that the ball member is formed from a ceramic material. The ball member may have a diameter of about 4 millimeters.

In addition to one or more of the features described above, or as an alternative, further examples of the substrate storage rack may include that the column assembly is a first column assembly and that the substrate storage rack includes one or more second column assemblies. The one or more second column assemblies may connect the top plate to the bottom plate. The one or more second column assemblies may be spaced apart from the first column assembly by between about 100 millimeters and about 300 millimeters. A shroud member may enclose each of the bottom plate, the top plate, the first column assembly, and the one or more second column assemblies.

In addition to one or more of the features described above, or as an alternative, further examples of the substrate storage rack may include that the column assembly has a column member and a clamp member. The column member may have a column portion extending longitudinally between the base plate and the top plate and a seating portion extending laterally from the column portion. The clamp member may have a base portion extending longitudinally along the column portion of the column member and a clamping portion extending laterally from the base portion of the clamp member. The clamping portion of the clamp member may compressively fix the ball member against the seating portion and within a pocket defined between the seating portion of the column member and the clamping portion of the clamp member.

In addition to one or more of the features described above, or as an alternative, further examples of the substrate storage rack may include at least one of the seating portions of the column member and the clamping portion of the clamp member that define a longitudinal slot with a rounded segment and a neck segment extending from the rounded segment. The rounded segment may have a diameter that is smaller than a diameter of the ball member. The ball member may be fixed within the rounded segment of the longitudinal slot.

In addition to one or more of the features described above, or as an alternative, further examples of the substrate storage rack may include that the seating portion of the column member defines the longitudinal slot.

In addition to one or more of the features described above, or as an alternative, further examples of the substrate storage rack may include that the longitudinal slot is a first longitudinal slot defined by the seating portion of the column member, that the clamping portion of the clamp member defines a second longitudinal, and that the ball member is further fixed within the second longitudinal slot.

In addition to one or more of the features described above, or as an alternative, further examples of the substrate storage rack may include a spacer member. The spacer member may couple the clamp member to the column member. The spacer member may have a thickness, the ball member may have a diameter, and the thickness of the spacer member may be smaller than the diameter of the ball member.

In addition to one or more of the features described above, or as an alternative, further examples of the substrate storage rack may include that the column portion is a first column portion and that the column member has a second column portion. The second column portion may extend in parallel with the first column portion. The second column portion may be connected to the first column member by the seating portion of the column member.

In addition to one or more of the features described above, or as an alternative, further examples of the substrate storage rack may include that the seating portion is a first seating portion and that the column member has one or more second seating portions. The one or more second seating portions may extend laterally from the column portion of the column member. The one or more second seating portions may be longitudinally spaced apart from the first seating portion along a longitudinal length of the column portion of the column member.

In addition to one or more of the features described above, or as an alternative, further examples of the substrate storage rack may include that the clamping portion of the clamp member is a first clamping portion and the clamp member has one or more second clamping portions. The one or more second clamping portions may be longitudinally spaced apart from the first clamping portion along a longitudinal length of the column portion of the column member.

In addition to one or more of the features described above, or as an alternative, further examples of the substrate storage rack may include that the clamp member is a first clamp member and that the column assembly includes one or more second clamp members. The one or more second clamp members may be connected to the column portion of the column member. The one or more second clamp members may be arranged longitudinally between the first clamp member and the top plate of the substrate storage rack.

In addition to one or more of the features described above, or as an alternative, further examples of the substrate storage rack may include that the ball member is a first ball member and that the column assembly includes one or more second ball members. The second ball member may be compressively seated within the column assembly. The one or more second ball members may protrude from the column assembly in a direction toward the top plate of the substrate storage rack. The one or more second ball members may be longitudinally spaced apart from the first ball member along a longitudinal length of the column portion of the column member.

In addition to one or more of the features described above, or as an alternative, further examples of the substrate storage rack may include that the column assembly includes a column member sheet body having a column member sheet thickness and a clamp member sheet body having a clamp member sheet thickness. The column member sheet thickness of the column member sheet body may be greater than the clamp member sheet thickness of the clamp member sheet body.

In addition to one or more of the features described above, or as an alternative, further examples of the substrate storage rack may include that the column member sheet thickness is between about 1 millimeter and about 10 millimeters, and that the clamp member sheet thickness is between about 1 millimeter and about 10 millimeters.

A pod, e.g., a front opening unified pod (FOUP), may be provided. The pod may include an enclosure and a substrate storage rack as described above. The enclosure may be arranged to be seated on a load port of a semiconductor processing system. The substrate storage rack is arranged within an interior of the enclosure.

A semiconductor processing system is provided. The semiconductor processing system may include a front-end module with a front-end transfer robot, a back-end module with a back-end transfer robot connected to the front-end module, a process module with a heater or susceptor connected to the back-end module, and a substrate storage rack as described above. The substrate storage rack may be arranged within a movement range of at least one of the front-end transfer robots and the back-end transfer robot. In certain examples, the substrate storage rack may be fixed relative to the front-end module. In accordance with certain examples, the substrate storage rack may be movable relative to the front-end module. It is also contemplated that the substrate storage rack may be movable relative to the semiconductor processing system, such as using an automated material handling system.

In addition to one or more of the features described above, or as an alternative, further examples of the semiconductor processing system may include that the front-end module comprises a notch aligner, and that the substrate storage rack is arranged above the notch aligner and within the front-end module.

In addition to one or more of the features described above, or as an alternative, further examples of the semiconductor processing system may include that the semiconductor processing system includes a load lock, and that the substrate storage rack is arranged within the load lock.

A method of making a substrate storage rack is provided. The method includes forming a column member with a column member and a seating portion using a column member sheet body, the seating member extending laterally from the column portion of the column member. A clamp member with a base portion and a clamping portion extending laterally from the base portion is formed using a clamp member sheet body. A ball member is seated on the seating portion of the column member, the clamp member is registered to the column member using the ball member, and the ball member is compressed between the seating portion of the column member and the clamping portion of the clamp member. The ball member is fixed in compression between the seating portion of the column member and the clamping portion of the clamp member by fastening the base portion of the clamp member to the column portion of the column member.

For purposes of summarizing the invention and the advantages achieved over the prior art, certain objects and advantages of the invention have been described above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 is a schematic view of a semiconductor processing system with a substrate storage rack in accordance with the present disclosure, showing the substrate storage rack arranged above a notch aligner and within a front-end module chamber of the semiconductor processing system;

FIG. 2 is a perspective view of the substrate storage rack of FIG. 1 according to a first example, showing column assemblies connecting a top plate to a bottom plate within a shroud to support substrates within slots defined by the column assemblies on ball members fixed within the column assembly;

FIG. 3 is a perspective view of a portion of the substrate storage rack of FIG. 1 according to the first example, showing ball members fixed between seating portions of a column member and clamping portions of clamp members by radial clamping forces to support substrates on the column assembly;

FIG. 4 is an exploded view of a portion of the substrate storage rack of FIG. 1 according to the first example, showing three clamp members and ball members exploded away from the column member of the column assembly;

FIGS. 5, 6, 7, 8, and 9 are plan and perspective views of components of the substrate assembly of FIG. 1 according to the first example, showing the ball member, the column member subsequent to stamping and subsequent to bending during fabrication, and the clamp member subsequent to stamping and subsequent to bending during fabrication;

FIG. 10 is a perspective view of the substrate storage rack of FIG. 1 according to a second example, showing column assemblies connecting a top plate to a bottom plate within a shroud to support substrates within slots defined by the column assemblies on ball members fixed within the column assembly;

FIG. 11 is a perspective view of a portion of the substrate storage rack of FIG. 1 according to the second example, showing ball members fixed between seating portions of a column member and clamping portions of a clamp member by tangential clamping forces to support substrates on the column assembly;

FIG. 12 is an exploded view of a portion of the substrate storage rack of FIG. 1 according to the first example, showing the clamp member, ball members, and a spacer member exploded away from the column member of the column assembly;

FIGS. 13, 14, and 15 are plan views of components of the substrate storage assembly of FIG. 1 according to the second example, showing the clamp member, the spacer member, and the column member subsequent to stamping each member;

FIG. 16 is a block diagram of a method for making a substrate storage rack in accordance with the present disclosure, showing operations according to an illustrative and non-limiting example of the method;

FIG. 17 is a perspective view of the substrate storage rack of FIG. 1 according to a third example;

FIG. 18A is a perspective view of components of a column assembly of the substrate storage rack of FIG. 17;

FIG. 18B is a side view of components of a column assembly of the substrate storage rack of FIG. 17;

FIG. 19 is a perspective view of the substrate storage rack of FIG. 1 according to a fourth example;

FIG. 20A is a perspective view of components of a column assembly of the substrate storage rack of FIG. 19;

FIG. 20B is a side view of components of a column assembly of the substrate storage rack of FIG. 19; and

FIG. 21 is a block diagram of a method for using a substrate storage rack in accordance with the present disclosure, showing operations according to an illustrative and non-limiting example of the method.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments. Further, in this disclosure, the terms “including,” “constituted by,” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments. In some cases, percentages indicated herein can be relative or absolute percentages.

A number of example materials are given throughout the embodiments of the current disclosure; it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

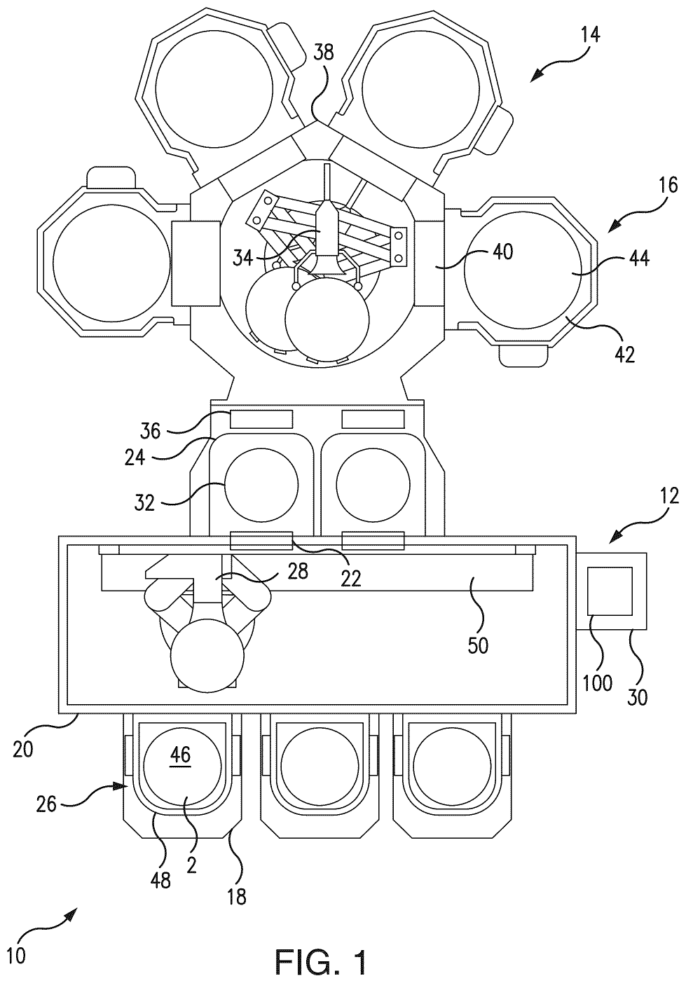

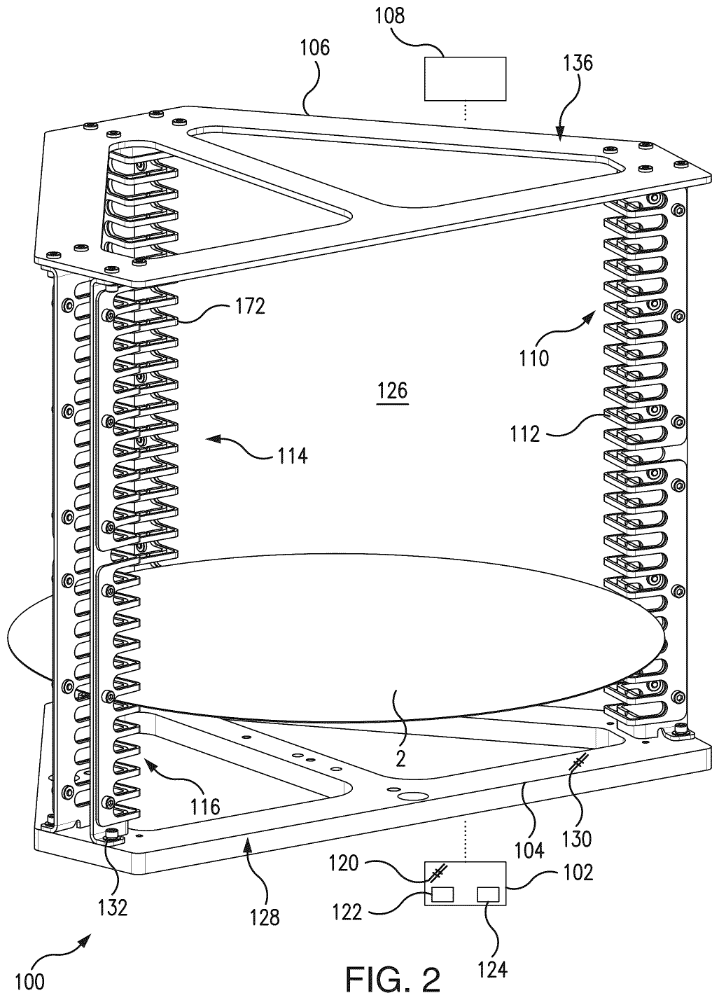

Reference will now be made to the drawings wherein like reference numerals identify similar structural features or aspects of the subject disclosure. For purposes of explanation and illustration, and not limitation, a partial view of an example of a substrate storage rack in accordance with the present disclosure is shown in FIG. 1 and is designated generally by reference character 100. Other examples of substrate storage racks, semiconductor processing systems, and methods of making substrate storage racks, or aspects thereof, are provided in FIGS. 2-20, as will be described. The substrate storage racks of the present disclosure may be used to store substrates during the fabrication of semiconductor devices, such as proximate to notch aligners or load locks in cluster-type semiconductor processing systems employed to deposit films onto substrates, though the present disclosure is not limited to any particular location or to semiconductor processing systems employed to deposit films onto substrates in general.

As used herein, a “substrate” refers to any material having a surface onto which material can be deposited. A substrate may include a bulk material such as silicon (e.g., single crystal silicon) or may include one or more layers overlaying the bulk material. Further, a substrate may include various topologies, such as trenches, vias, lines, and the like formed within or on at least a portion of a layer of the substrate. A substrate may include a silicon wafer, such as a 200-millimeter silicon wafer, a 300-millimeter silicon wafer, or even a 450-millimeter silicon wafer.

Referring to FIG. 1, a semiconductor processing system 10 is shown. The semiconductor processing system 10 may include a front-end module 12, a back-end module 14, and a process module 16. The front-end module 12 may include a load port 18, a front-end enclosure 20, a front-end gate valve 22, a load lock chamber 24, and the substrate storage rack 100. The load port 18 may be configured to seat thereon a pod 26, e.g., a front-opening unified pod (FOUP) containing a substrate 2, to move substrates to and from the semiconductor processing system 10. The pod 26 may comprise one or more substrate storage racks, such as the substrate storage rack 100, to store the substrate 2. The front-end enclosure 20 may be connected to the load port 18 and house a front-end transfer robot 28, a notch aligner 30, and the substrate storage rack 100. The front-end transfer robot 28 may be supported for movement within the front-end enclosure 20, have a movement envelope including the substrate storage rack 100, and be configured to transport substrates, e.g., the substrate 2, between the load port 18 and the load lock chamber 24 using the substrate storage rack 100. The notch aligner 30 may be supported within the front-end enclosure 20 and may be configured to notch-align substrates, e.g., imparting one or more of a predetermined x-shift, y-shift, and rotation in the substrate, within the front-end enclosure 20. The front-end gate valve 22 may be connected to the front-end enclosure 20, may couple the front-end enclosure 20 to the load lock chamber 24, and may be configured to provide selective communication between the front-end enclosure 20 and the load lock chamber 24. The load lock chamber 24 may be connected to the front-end gate valve 22, and therethrough to the front-end enclosure 20, and may include a chill plate 32 and/or a park station. The load lock chamber 24 may comprise one or more substrate storage racks, such as the substrate storage rack 100, to store the substrate 2. Although shown and described herein as having three (3) load ports and two (2) load locks, it is to be understood and appreciated that the semiconductor processing system 10 may have fewer or additional load ports and load locks and remain within the scope of the present disclosure.

The back-end module 14 may be connected to the front-end module 12 and include the back-end transfer robot 34, a back-end gate valve 36, and a back-end chamber 38. The back-end gate valve 36 may be connected to the load lock chamber 24 and may be configured to provide selective communication between the load lock chamber 24 and the back-end chamber 38. The back-end chamber 38 may be connected to the back-end gate valve 36 and house the back-end transfer robot 34. The back-end transfer robot 34 may be supported within the back-end chamber 38 for movement relative to the load lock chamber 24, may have a movement envelope encompassing both the load lock chamber 24 and the process module 16, and may be configured to transport substrates, e.g., the substrate 2, between the load lock chamber 24 and the process module 16. Although shown and described herein as having a singular back-end module, it is to be understood and appreciated that the semiconductor processing system 10 may have more than one back-end module and remain within the scope of the present disclosure.

The process module 16 may include a process module gate valve 40, a reaction chamber 42, and a susceptor or heater 44. The process module gate valve 40 may be connected to the back-end module 14, couple the back-end chamber 38 to the reaction chamber 42, and be configured to provide selective communication between the back-end module 14 and the process module 16. The reaction chamber 42 may be connected to the back-end chamber 38 and house the susceptor or heater 44. The susceptor or heater 44 may be supported within the reaction chamber 42 and be configured to support substrates, e.g., the substrate 2, during processing of the substrates. In certain examples, the susceptor or heater 44 may be configured to support the substrate 2 during deposition of a film onto the substrate 2. In accordance with certain examples, the susceptor or the heater 44 may be configured to support the substrate 2 during the removal of a film from the surface of the substrate 2. Although shown and described herein in the context of a semiconductor processing system configured for depositing films onto substrates, it is to be understood and appreciated that semiconductor processing systems configured for performing other processing operations may also benefit from the present disclosure. Further, it is to be understood and appreciated that semiconductor processing systems having fewer or additional process modules, as well as process modules including more than one reaction chamber, may also benefit from the present disclosure.

In certain examples, the substrate storage rack 100 may be supported within the front-end module 12 and/or within a movement range 50 of the front-end transfer robot 28. In this respect, the substrate storage rack 100 may be supported within the front-end enclosure 20 and above the notch aligner 30. So positioned, the substrate storage rack 100 may enable staging substrates in proximity to the notch aligner 30, improving throughput in processes where notch alignment could otherwise constrain throughput. Alternatively (or additionally), the substrate storage rack 100 may be supported within the load lock chamber 24, for example and above the chill plate 32. Positioning the substrate storage rack 100 within the load lock chamber 24 enables staging substrates in proximity to the chill plate 32, improving throughput in processes where substrate cooling could otherwise constrain throughput. It is also contemplated that, in accordance with certain examples, the substrate storage rack 100 may be arranged within an interior 46 of an enclosure 48 employed to transfer substrates to and from the semiconductor processing system 10, e.g., the pod 26. As will be appreciated by those of skill in the art in view of the present disclosure, this can limit particle generation due to the point support regime employed within the substrate storage rack 100.

With reference to FIG. 2, the substrate storage rack 100 is shown. The substrate storage rack 100 may include a base plate 102, a bottom plate 104, a top plate 106, and a shroud 108. The substrate storage rack 100 may also include a column assembly 110 defining one or more slots 112 configured to seat a substrate, e.g., the substrate 2, within the one or more slots 112. In the illustrated example, the column assembly 110 may be a first column assembly 110, and the substrate storage rack 100 may include a second column assembly 114 and a third column assembly 116. The second column assembly 114 may be similar to the first column assembly 110, extend in parallel with the first column assembly 110, and be offset from the first column assembly 110. The third column assembly 116 is also similar to the first column assembly 110, further extends in parallel with the first column assembly 110 and is further offset from both the first column assembly 110 and the second column assembly 114. In certain examples, the second column assembly 114 may be separated from the first column assembly 110 by less than about 300 millimeters. In accordance with certain examples, one or more of the second column assembly 114 and the third column assembly 116 may be offset from the first column assembly 110 by about 90 degrees from a center of the substrate 2. The first column assembly 110, the second column assembly 114, and the third column assembly 116 may form an obtuse isosceles triangle. The column assemblies 110, 114, and 116 may be arranged in such a way that the substrate 2 may be transferred into or out of the substrate storage rack 100 by using the opening between the first column assembly 110 and the third column assembly 116. Although shown and described herein is a substrate storage rack 100 having three column assemblies, it is to be understood and appreciated that the substrate storage rack 100 may have fewer or additional column assemblies and remain within the scope of the present disclosure.

The base plate 102 may include a base plate body 118. The base plate body 118 may be formed from a metallic material 120, have a base plate fastener pattern 122, and define a base plate aperture 124. The metallic material 120 may include an aluminum-containing or stainless-steel material, such as 4040 aluminum or 304 stainless steel, which simplifies fabrication of the substrate storage rack 100 by eliminating the need to coat or paint the substrate storage rack 100. The base plate fastener pattern 122 may be configured to both connect the substrate storage rack 100 to the semiconductor processing system 10 (shown in FIG. 1) and the bottom plate 104 to the base plate body 118. The base plate aperture 124 may extend through the base plate body 118, couple an upper surface of the base plate body 118 to a lower surface of the base plate body 118, and be configured to provide fluid communication between an interior 126 of the substrate storage rack 100 and the interior of the semiconductor processing system 10. In the illustrated example, the base plate 102 may be configured to support the substrate storage rack 100 within the front-end enclosure 20 of the front-end module 12 at a location above the notch aligner 30 (shown in FIG. 1). As will be appreciated by those of skill in the art in view of the present disclosure, support of the substrate storage rack 100 in proximity to the notch aligner 30 may provide capability to store substrates, e.g., the substrate 2, in proximity to the notch aligner 30, limiting the tendency of the notch aligner 30 to constrain throughput in processes that require rotationally aligning substrates prior to transporting substrates to the process module 16.

The bottom plate 104 may include a bottom plate body 128. The bottom plate body 128 may be formed from a metallic material 130, have a bottom plate fastener pattern 132, and define a bottom plate aperture 134. The metallic material 130 may include an aluminum-containing or stainless-steel material, such as 4040 aluminum or 304 stainless steel. The bottom plate fastener pattern 132 may connect each of the first column assembly 110, the second column assembly 114, and the third column assembly 116 to the bottom plate body 128. The bottom plate aperture 134 may overlap the base plate aperture 124 and fluidly couple the interior 126 of the substrate storage rack 100 to the base plate aperture 124.

The top plate 106 includes a top plate body 136. The top plate body 136 may be formed from a metallic material 138, have a top plate fastener pattern 140, and define a top plate aperture 142. The metallic material 138 may include an aluminum-containing or stainless-steel material, such as 4040 aluminum or 304 stainless steel. The top plate fastener pattern 140 may connect the top plate body 136 to each of the first column assembly 110, the second column assembly 114, and the third column assembly 116, and therethrough to the bottom plate 104. The top plate aperture 142 may fluidly couple to the interior 126 of the substrate storage rack 100, and therethrough to the bottom plate aperture 134.

The shroud 108 may include a shroud body 144. The shroud body 144 may be formed from a metallic material 146, bounds the interior 126 of the substrate storage rack 100, and may have an inlet 148 and an outlet 150. The metallic material 146 may include an aluminum-containing or stainless-steel material, such as 4040 aluminum or 304 stainless steel. The inlet 148 may be separated from the second column assembly 114 and the third column assembly 116 by the first column assembly 110. The outlet 150 may be separated from the first column assembly 110 by the second column assembly 114 and the third column assembly 116. It is contemplated that the inlet 148 may be fluidly coupled to a fan-filter unit supported within an upper recess of the front-end module 12, that the outlet 150 be fluidly coupled to an interior of the front-end enclosure 20, and that shroud 108 be configured to flow filtered air from the inlet 148 to the outlet 150 and across a substrate, e.g., the substrate 2 (shown in FIG. 1), seated within the one or more slot 112 while stored within the substrate storage rack 100.

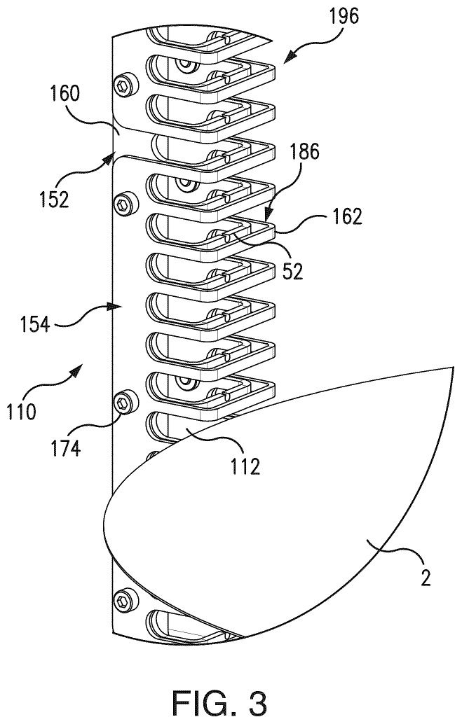

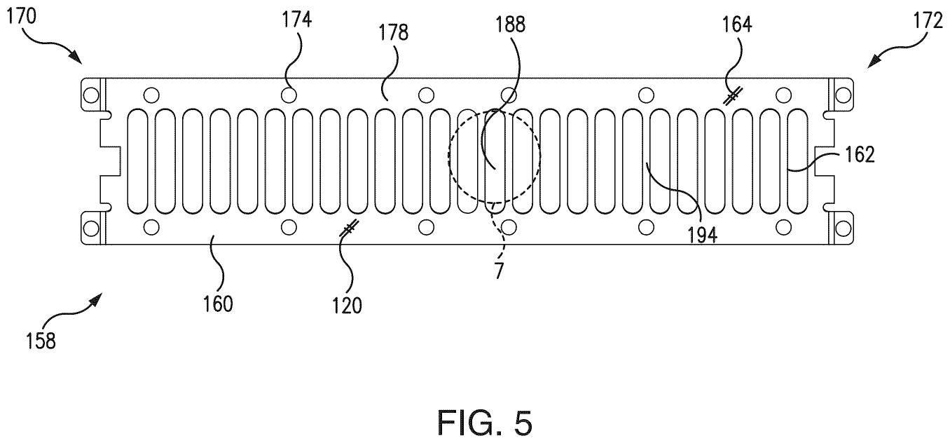

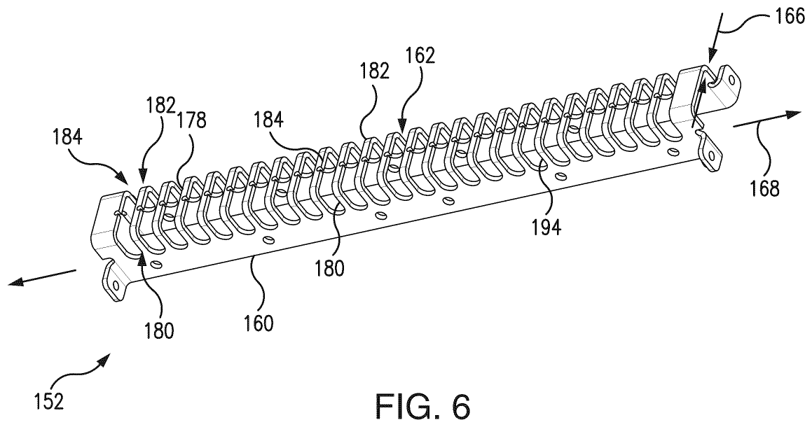

With reference to FIG. 3, the first column assembly 110 may include a column member 152, a clamp member 154, and a ball member 156. The column member 152 may include a column member sheet body 158 (shown in FIG. 5) having a column portion 160 and a seating portion 162 (shown in FIG. 5). The column member sheet body 158 may be formed from a metallic sheet material 164 (shown in FIG. 5) such as 4040 aluminum or 304 stainless steel and has a thickness 166 (shown in FIG. 6). The thickness 166 may be between about 1 millimeter and about 10 millimeters, or between about 2 millimeters about 8 millimeters, or even between about 3 millimeters and about 6 millimeters. In certain examples, the thickness 166 may be about 2 millimeters. As will be appreciated by those of skill in the art in view of the present disclosure, thicknesses within these ranges allow the column member 152 to be formed from planar sheet stock using a stamping and succeeding bending operation. This may simplify fabrication of the column assembly 110 as it eliminates the need to machine slots into quartz or polyether ether ketone (PEEK) bar stock material, and thereafter support the slotted body on a structural member, simplifying fabrication of the substrate storage rack 100 (shown in FIG. 1).

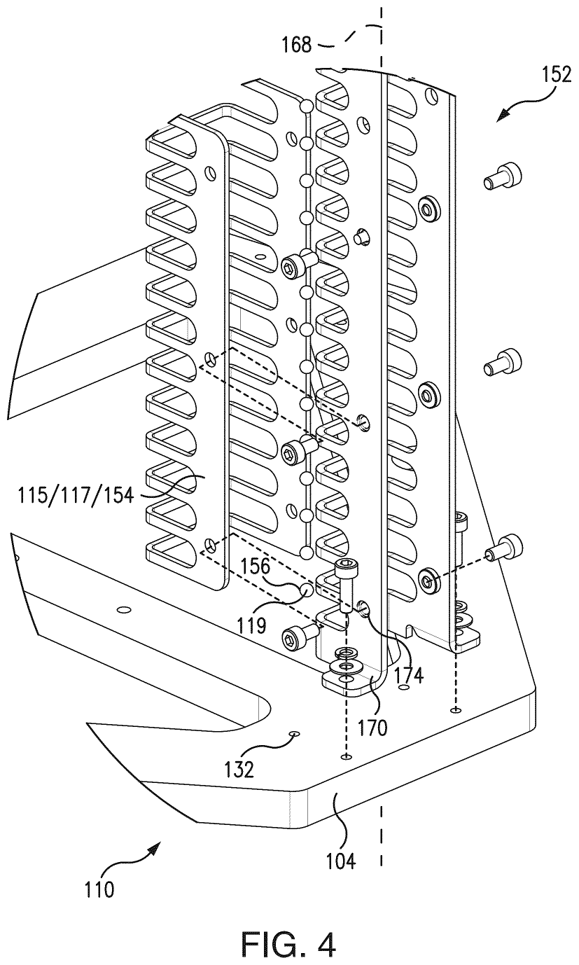

With reference to FIG. 4, the column portion 160 of the column member 152 may define a column member axis 168 and have a bottom fastener tab 170, a top fastener tab 172, and one or more fastener apertures 174. The bottom fastener tab 170 may extend laterally from the column portion 160 and may be configured to connect the column member 152 to the bottom plate 104 using the bottom plate fastener pattern 132. The top fastener tab 172 may extend laterally from the column portion 160 at an end opposite the bottom fastener tab 170 and may be configured to connect the column member 152 to the top plate 106 using the top plate fastener pattern 140. The one or more fastener apertures 174 may extend through the column portion 160 at a location longitudinally between the bottom fastener tab 170 and the top fastener tab 172 and may be configured to couple the clamp member 154 to the column member 152.

In certain examples, the column portion 160 of the column member 152 may define a plurality of fastener apertures 174 extending through the column member sheet body 158. In such examples, the plurality of fastener apertures 174 may connect a singular clamp member 154 to the column member 152, increasing the stiffness of the column assembly 110. In accordance with certain examples, the clamp member 154 may be a first clamp member 154 and the plurality of fastener apertures 174 may connect at a second clamp member 176 to the column member 152, increasing the number of substrates that may be stored in the substrate storage rack 100. It is contemplated that one or more of the top fastener tabs 172 and the bottom fastener tab 170 may be portions of the column member 152, such as formed using a pressing or bending application, such as with a press brake. It is also contemplated that one or more of the top fastener tabs 172 and the bottom fastener tab 170 may be fastened to the column member 152. As will be appreciated by those of skill in the art in view of the present disclosure, employment of fastened tabs can simplify fabrication of the column assembly 110 by limiting (or eliminating) the tolerance consequences of forming either (or both) the top fastener tab 172 and or the bottom fastener tab 170 using a pressing or bending operation.

With reference to FIGS. 5 and 6, the column portion 160 may be a first column portion 160, and the column member 152 may have a second column portion 178. In such examples, the second column portion 178 may be similar to the first column portion 160 and may be additionally arranged on a side of the column member axis 168 opposite the first column portion 160. It is contemplated that the second column portion 178 be connected to the first column portion 160 by the seating portion 162. The seating portion 162 may have a first lateral segment 180 extending laterally from the first column portion 160 of the column member 152, a second lateral segment 182 extending laterally from the second column portion 178 of the column member 152, and an arcuate segment 184 spanning the column member axis 168 and connecting the first lateral segment 180 to the second lateral segment 182.

It is contemplated that the ball member 156 (shown in FIG. 4) be seated on the seating portion 162 of the column member 152. In this respect, the clamp member 154 and the seating portion 162 of the column member 152 may define a pocket 186 (shown in FIG. 3) between one another, the ball member 156 is at least partially captive within the pocket 186, and a protruding portion 196 of the ball member 156 protrudes from the pocket 186. In further respect, the seating portion 162 of the clamp member 154 (shown in FIG. 3) may laterally overlay both the ball member 156 and the arcuate segment 184 of the seating portion 162 to exert a radial clamping force 52 (shown in FIG. 3) on the ball member 156, i.e., exerted along an axis intersecting the center of a circular substrate positioning within the substrate storage rack 100, the radial clamping force 52 fixing the ball member 156 within column assembly 110.

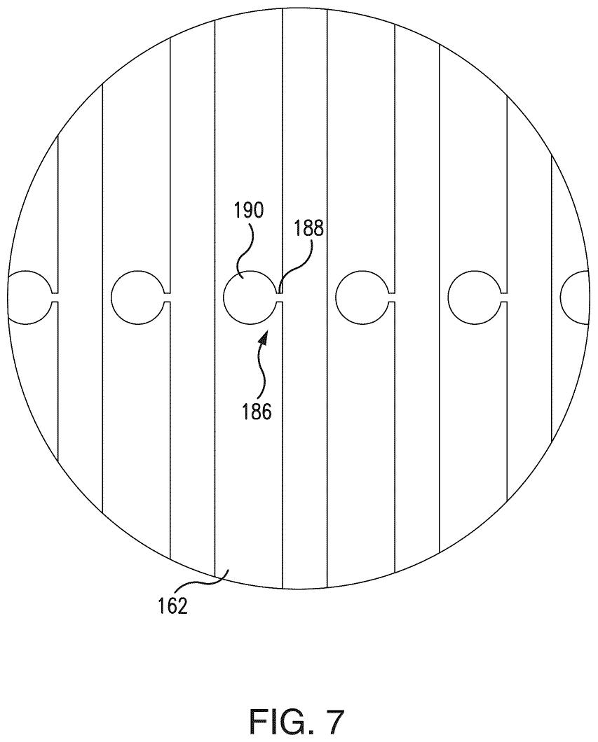

With reference to FIG. 7, at least one of the arcuate segments 184 and the clamp member 154 may define a longitudinal slot 188 within the pocket 186. In such examples, the ball member 156 (shown in FIG. 3) may be captive within the pocket 186 between the arcuate segment 184 and the clamp member 154 at a position defined by the geometry of the longitudinal slot 188. For example, the longitudinal slot 188 may include a neck segment 190 and a rounded segment 192. The neck segment 190 may extend upwards from the rounded segment 192 and have a width that is smaller than a diameter of the rounded segment 192. The rounded segment 189 may have a diameter that is smaller than a diameter of the ball member 156. As will be appreciated by those of skill in the art in view of the present disclosure, sizing the rounded segment 192 of the longitudinal slot 188 with a diameter that is less than the diameter of the ball member 156 can simplify fabrication of the column assembly 110 (shown in FIG. 2). In this respect the rounded segment 192 of the longitudinal slot 188 may register the ball member 156 relative to the seating portion 162 of the column member 152. The rounded segment 192 may further retain the position of the ball member 156 during assembly of the clamp member 154 onto the column member 152, limiting (or eliminating) the need for a specialized jig to otherwise support the ball member 156 during the assembly process. The longitudinal slot 188 may be formed using a stamping operation, a punching operation, or a broaching operation. For example, a relatively low-cost push or pull operation may be employed to form the longitudinal slot 188 instead of a more complex and/or costly rotary broaching operation.

With continuing reference to FIGS. 5 and 6, the seating portion 162 may be a first seating portion 162, and the column member 152 may have one or more second seating portions 194. In such examples the second seating portion 194 may be similar to the first seating portion 162 and additionally offset longitudinally from the first seating portion 162 along the column member 152 by a height of the one or more slot 112 (shown in FIG. 3). In this respect the height of the one or more slot 112 may be defined between a contact point on a protruding portion 196 (shown in FIG. 3) of the ball member 156 extending upwards from the pocket 186, the protruding portion 196 above both the seating portion 162 of the column member 152 and a clamping portion 198 of the clamp member 154. The height of the one or more slots 112 may be between about 1 millimeter and about 10 millimeters, or between 2 millimeters and about 9 millimeters, or between about 4 millimeters and about 8 millimeters. In certain examples, the height of the one or more slots 112 may be about 6 millimeters. As will be appreciated by those of skill in the art in view of the present disclosure, heights within these ranges allow an end effector of the front-end transfer robot 28 (shown in FIG. 1) to move upwards and downwards within the interior 126 of the substrate storage rack 100 to place and retrieve substrates, e.g., the substrate 2 (shown in FIG. 1), in the one or more slot 112. In the illustrated example, the column member 152 has 30 seating portions longitudinally spaced apart from one another along the length of the column member 152. As will also be appreciated by those of skill in the art in view of the present disclosure, the column member 152 may have fewer or additional seating portions than shown in the illustrated example and remain within the scope of the present disclosure.

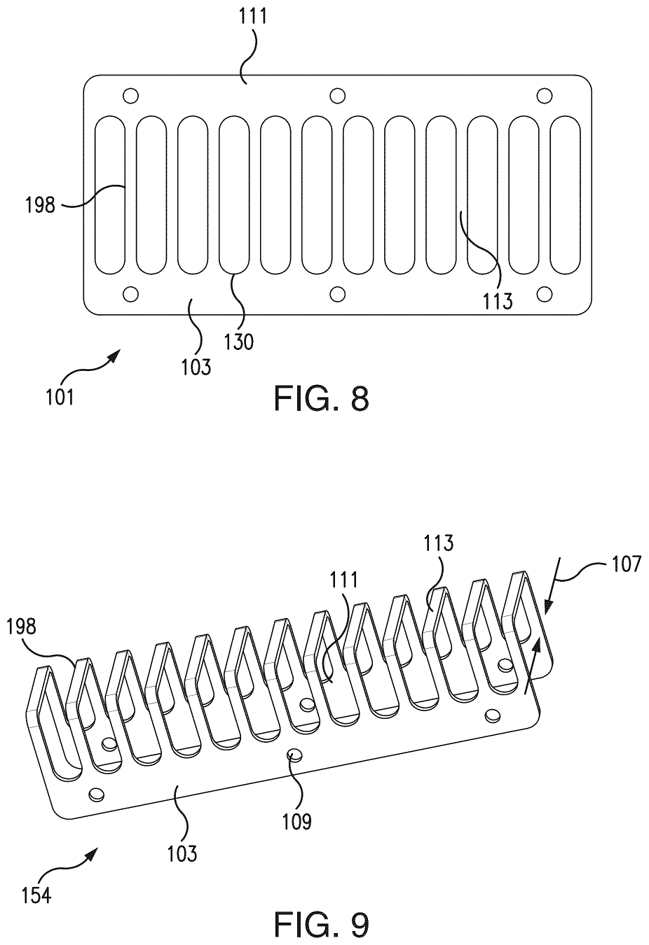

With reference to FIGS. 8 and 9, the clamp member 154 may include a clamp member sheet body 101 with the clamping portion 198 and a base portion 103. The clamp member sheet body 101 may be formed from metallic sheet material 105 and have a thickness 107. The metallic sheet material 105 may include an aluminum-containing or stainless-steel material, such as 4040 aluminum or 304 stainless steel. In certain examples, the thickness 107 of the clamp member sheet body 101 may be between about 1 millimeter and about 10 millimeters, or between about 1 millimeter and about 6 millimeters, or even between about 1 millimeter and about 2 millimeters. In accordance with certain examples, the thickness 107 may be about 1.5 millimeters. As will be appreciated by those of skill in the art in view of the present disclosure, thicknesses within these ranges also allow the clamp member 154 to be formed from planar sheet stock using a stamping and a subsequent bending operation. Forming the clamp member 154 using stamping and bending operations can simplify fabrication of the column assembly 110, for example, by eliminating machining operations otherwise required to define slots into bar stock formed from a material suitable for substrate contact, such as quartz or PEEK stock.

In certain examples, the base portion 103 of the clamp member 154 may extend in parallel with the first column portion 160 of the column member 152. In accordance with certain examples, the base portion 103 of the clamp member 154 may be spaced apart from the column member axis 168 (shown in FIG. 4) by the first column portion 160 (shown in FIG. 5) of the column member 152 (shown in FIG. 3). It is also contemplated that the clamp member 154 may have one or more fastener aperture 109 Shown in FIG. 5), and that the base portion 103 of the clamp member 154 may be connected to the first column portion 160 by one or more fasteners received in the fastener aperture 109 of the base portion 103 and the one or more fastener apertures 174 of the first column portion 160. As will be appreciated by those of skill in the art in view of the present disclosure, this provides the column assembly 110 with a composite construction that limits the thickness otherwise required by the column member sheet body 158 and the clamp member sheet body 101, simplifying the stamping and bending operations used to form the column member 152 and the clamp member 154 from the column member sheet body 158 and the clamp member sheet body 101, respectively.

The clamping portion 198 of the clamp member 154 may extend laterally from the base portion 103 of the clamp member 154. The clamping portion 198 may further laterally overlay both the ball member 156 (shown in FIG. 3) and the seating portion 162 of the column portion 160. It is contemplated that the clamping portion 198 urge the ball member 156 toward the seating portion 162 (shown in FIG. 5) of the column member 152 (shown in FIG. 3), compressing the ball member 156 within the pocket 186 (shown in FIG. 3) such that the ball member 156 is captive between the seating portion 162 of the column member 152 and the clamping portion 198 of the clamp member 154 by the radial clamping force 52 (shown in FIG. 3). As will be appreciated by those of skill in the art in view of the present disclosure, clamping the ball member 156 between the clamp member 154 and the column member 152 limits the number or parts otherwise required to fix the ball member 156 within the pocket 186, simplifying fabrication of the column assembly 110.

In certain examples, the base portion 103 of the clamp member 154 may be a first base portion 103, and the clamp member 154 may have a second base portion 111. In such examples, the second base portion 111 may extend in parallel with the first base portion 103. The second base portion 111 may be connected to the first base portion 103 of the clamp member 154 by the clamping portion 198 of the clamp member 154. The second base portion 111 may also be spaced apart from the first base portion 103 by both the first column portion 160 (shown in FIG. 5) and the second column portion 178 (shown in FIG. 5) of the column member 152 (shown in FIG. 3). In this respect the first base portion 103 of the clamp member 154 (shown in FIG. 3) may be fastened to the first column portion 160 and the second base portion 111 may be fastened to second column portion 178 to be fix the clamp member 154 to the column member 152 as well as to clamp the ball member 156 within the column assembly 110 (shown in FIG. 2) between the column member 152 and the clamp member 154. As will be appreciated by those of skill in the art in view of the present disclosure, fastening the first base portion 103 and the second base portion 111 to the first column portion 160 and the second column portion 178 of the column member 152, respectively, can increase the stiffness of the column assembly 110. Increasing the stiffness of the column assembly 110 in turn allows the column member sheet body 158 and the clamp member sheet body 101 to be relatively thin, simplifying fabrication of the column assembly 110.

In certain examples, the clamping portion 198 may be a first clamping portion 198, and the clamp member 154 may have one or more second clamping portions 113. In such examples, the second clamping portion 113 may be similar to the first clamping portion 198 and may be longitudinally spaced apart from the first clamping portion 198 along the longitudinal length of the first base portion 103 and the second base portion 111 of the clamp member 154. The second clamping portion 113 may be one of two clamping portions longitudinally spaced along the first base portion 103 and the second base portion 111 of the clamp member 154. The second clamping portion 113 may be one of two or more second clamping portions longitudinally spaced along the first base portion 103 and the second base portion 111 of the clamp member 154. For example, the second clamping portion 113 may be one of ten (10) or eleven (11) clamping portions longitudinally spaced along first base portion 103 and the second base portion 111 of the clamp member 154, the clamp member 154 having fewer clamping portions than seating portions of the column member 152. As will be appreciated by those of skill in the art in view of the present disclosure, clamp members having fewer clamping portions than seating portions of the column member can simplify fabrication of the column assembly, for example, by limiting the number of ball members positioned between the clamp member and the column member during assembly of the clamp member to the column member.

With continuing reference to FIG. 4, the clamp member 154 may be a first clamp member 154, and the column assembly 110 may further include a second clamp member 115 and a third clamp member 117. In such examples, the second clamp member 115 and the third clamp member 117 may be similar to the first clamp member 154. The second clamp member 115 may be connected to the column member 152 at a location longitudinally between the first clamp member 154 and the top fastener tab 172, the third clamp member 117 may be connected to the column member 152 at a location longitudinally between the second clamp member 115 and the top fastener tab 172, and connection may be accomplished by fasteners received within the second clamp member 115 and the third clamp member 117. Advantageously, column assemblies having more than one clamp member simplify assembly of the column assembly by limiting the number of ball members to a number manageable by a single assembler, e.g., by limiting the number of ball members to ten (10) or eleven (11) ball members. Although shown and described herein as having three (3) clamp members, it is to be understood and appreciated that the column assembly 110 can have fewer or additional clamp members and remain within the scope of the present disclosure. Further, although shown and described herein as having a particular number of clamping portions, the second clamp member 115 having eleven (11) clamping portions while the first clamp member 154 and the third clamp member 117 having ten (10) clamping portions, it is to be understood and appreciated that the column assembly 110 can have one or more clamp member with fewer or additional clamping portions and remain within the scope of the present disclosure.

It is contemplated that the ball member 156 be formed from a ball member material 119. The ball member 156 may also have a diameter that is between about 1 millimeter and 10 millimeters, or between 2 millimeters and about 8 millimeters, or even between about 3 millimeters and about 6 millimeters. The ball member 156 may have a diameter that is about 4 millimeters. As will be appreciated by those of skill in the art, diameters within these ranges allow the ball member 156 to be both captive within the pocket 186 (shown in FIG. 3) and protrude in part above both the seating portion 162 (shown in FIG. 5) of the column member 152 and the clamping portion 198 (shown in FIG. 4) of the clamp member 154. Protrusion above the seating portion 162 and the clamping portion 198 allows the ball member 156 to space a substrate, the substrate 2 (shown in FIG. 1), with sufficient distance to avoid contact between the underside of the substrate and the seating portion 162 of the column member 152 as well as the clamping portion 198 of the clamp member 154. As will be appreciated by those of the skill in the art in view of the present disclosure, avoiding contact allows the metallic material 120 and/or the metallic material 130 forming the column member 152 and the clamp member 154 to include alloying elements otherwise prohibited is front-end (copper-free) semiconductor processing systems, such as copper, that can simplify die pressing and/or bending metallic sheet stock.

In certain examples, the ball member material 119 may include a ceramic material. For example, the ball member material 119 may include silicon nitride (Si3N4), zinc oxide (ZnO3), aluminum oxide (Al2O3), or quartz. In accordance with certain examples, the ball member material 119 may consist of or consist essentially of a ceramic material, silicon nitride (Si3N4), zinc oxide (ZnO3), aluminum oxide (Al2O3), or quartz. As will be appreciated by those of skill in the art in view of the present disclosure, such materials limit the size of particulate shed during placement and removal of substrates from within the substrate storage rack 100, facilitating removal of the particulate with filtered air provided to the substrate storage rack 100. In certain examples the ball member material 119 may be matched to that forming contact pads carried by the end effector of either (or both) the front-end transfer robot 28 (shown in FIG. 1) and the back-end transfer robot 34 (shown in FIG. 1). As will also be appreciated by those of skill in the art in view of the present disclosure, matching the ball member material 119 to that forming the contact pads carried by the end effector of either (or both) the front-end transfer robot 28 and the back-end transfer robot 34 limits the potential sources of contamination within the semiconductor processing system 10. Examples of suitable ball members include G5 silicon nitride ceramic ball bearings, available from BC Precision of Chattanooga, Tennessee.

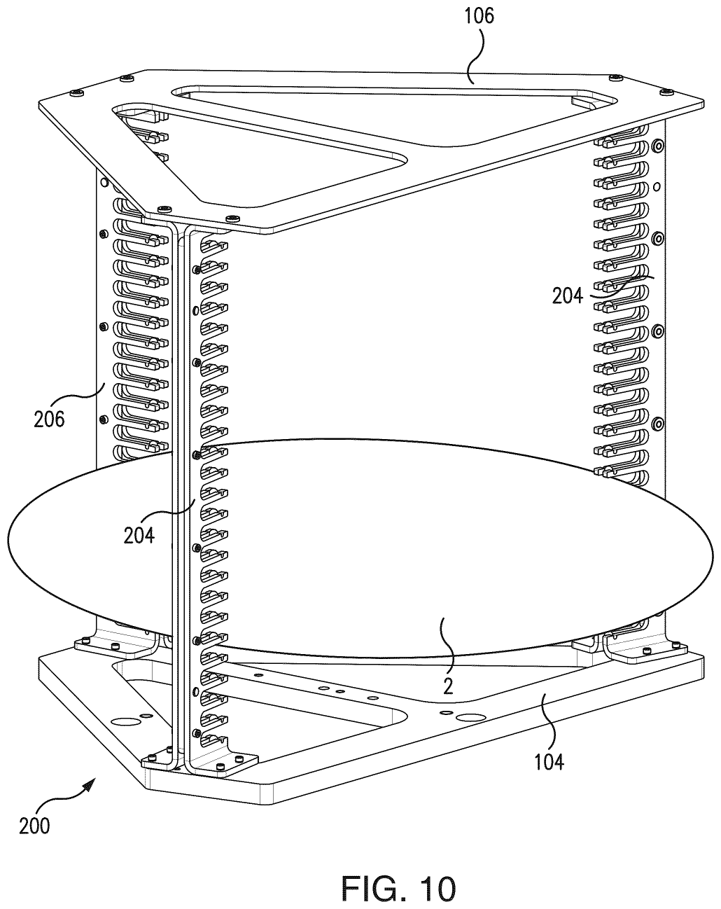

With reference to FIGS. 10-15, a substrate storage rack 200 is shown. Referring to FIG. 10, the substrate storage rack 200 is similar to the substrate storage rack 100 (shown in FIG. 1) and additionally includes a column assembly 202. It is contemplated that the column assembly 202 may be a first column assembly 202 and that the substrate storage rack 200 may further include a second column assembly 204 and a third column assembly 206. The first column assembly 202 connects the top plate 106 to the bottom plate 104 and defines a plurality of slots 208 between the top plate 106 and the bottom plate 104. The second column assembly 204 and the third column assembly 206 are similar to the first column assembly 202 and are additionally offset from one another about the center of the substrate 2. In the illustrated example, the second column assembly 204 and the third column assembly 116 are offset from the first column assembly 202 by about 90-degrees about the center of the substrate 2. In the illustrated example, the third column assembly 206 is further spaced apart from the second column assembly by a distance that is less that the diameter of the substrate 2. For example, the third column assembly 206 may be spaced apart from the second column assembly by less than about 300 millimeters, or less than 290 millimeters, or even less than about 280 millimeters. As above, the substrate storage rack 200 may have fewer column assemblies or more column assemblies than shown in the illustrated example and remain within the scope of the present disclosure.

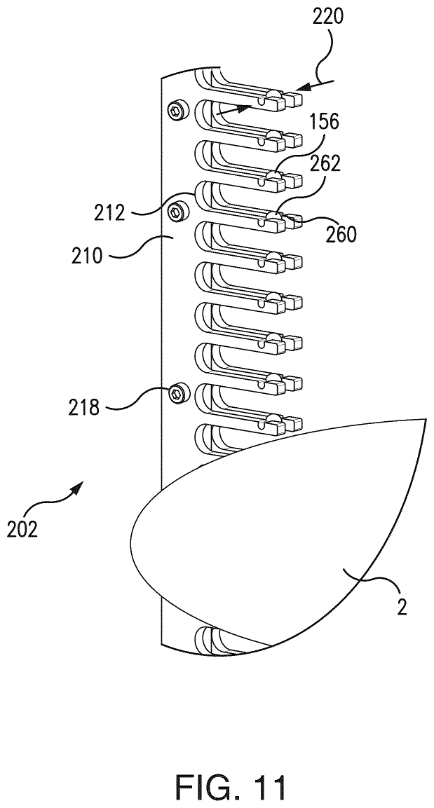

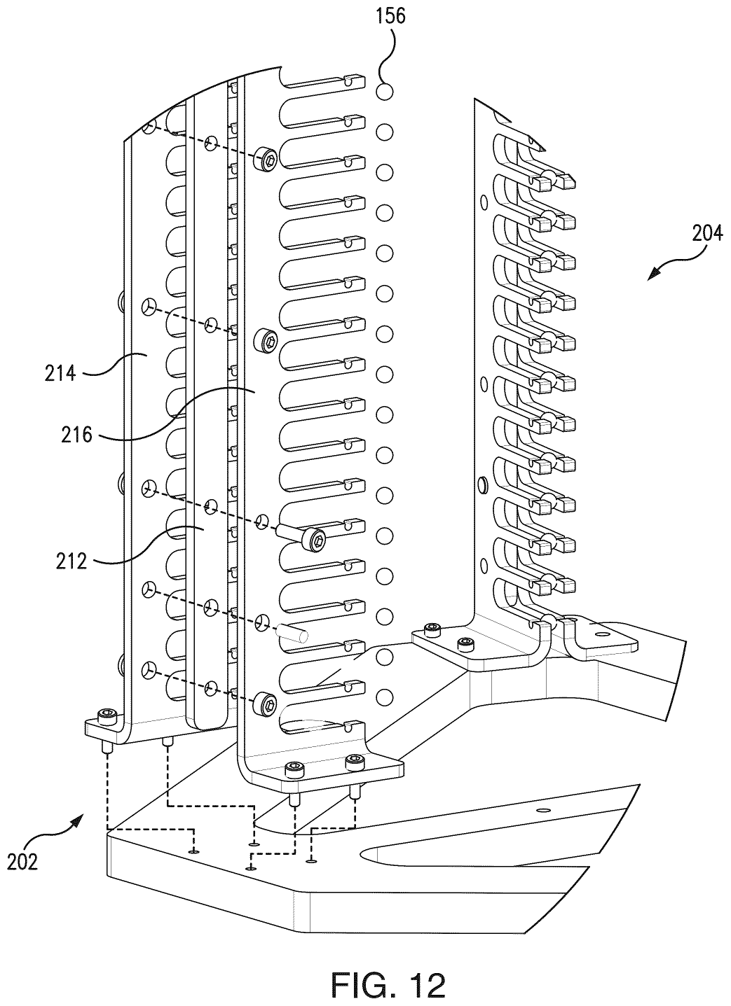

Referring to FIGS. 11 and 12, the first column assembly 202 includes a column member 210, a spacer member 212, a clamp member 214, and a plurality of ball members 156. The column member 210 extends longitudinally between the bottom plate 104 (shown in FIG. 2) and the top plate 106 (shown in FIG. 2). The spacer member 212 is arranged along a spacer member axis 216, is connected to the column member 210, and is parallel to the column member 210. The clamp member 214 is separated from the column member 210 by the spacer member 212, is coupled to the column member 210 by the spacer member 212 and extends in parallel with the column member 210. It is contemplated that the column member 210 and the clamp member 214 be compressively connected to one another by a plurality of fasteners 218 extending through the spacer member 212 and longitudinally spaced apart from one another along the spacer member axis 216. It is also contemplated that the plurality of ball members 156 be captive between the column member 210 and the clamp member 214 at locations radially inward of the spacer member 212. In this respect, the plurality of ball members 156 are fixed within the column assembly 202 by tangential clamping forces 220 exerted by the column member 210 and the clamp member 214.

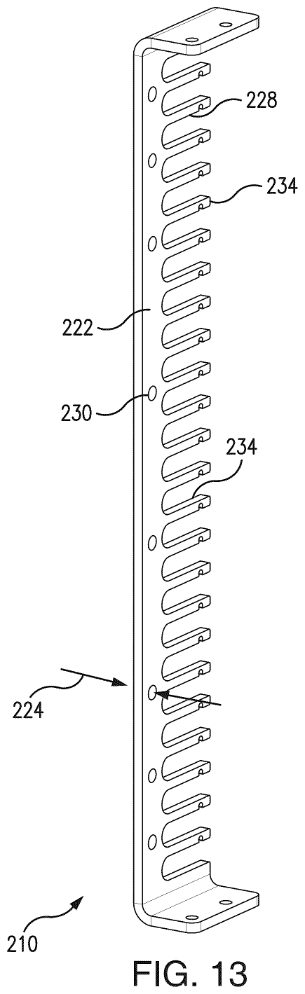

Referring to FIG. 13, the column member 210 includes a column member plate body 222 with a thickness 224, a column portion 226, and a seating portion 228. The column member plate body 222 may be formed from a metallic material 230, such as an aluminum-containing alloy or stainless steel. Examples of suitable aluminum-containing alloys and stainless-steel materials include 4040 aluminum and 304 stainless steel. In certain examples, the thickness 224 of the column member plate body 222 may be greater than the thickness 107 (shown in FIG. 9) of the clamp member sheet body 101 (shown in FIG. 8). In accordance with certain examples, the thickness 224 of the column member plate body 222 may be greater than the thickness 166 (shown in FIG. 6) of the column member sheet body 158 (shown in FIG. 5). For example, the thickness 224 of the column member plate body 222 may be between about 2 millimeters and about 20 millimeters, or between about 2 millimeters and about 15 millimeters, or even between about 2 millimeters and about 10 millimeters. The thickness 224 of the column member plate body 222 may be about 3 millimeters. As will be appreciated by those of skill in the art in view of the present disclosure, thicknesses within the ranges simplify fabrication of the column member 210.

The column portion 226 of the column member 210 has a longitudinal length 232 (shown in FIG. 10) spanning the bottom plate 104 (shown in FIG. 2) and the top plate 106 (shown in FIG. 2) of the substrate storage rack 200. The seating portion 228 of the column member 210 protrudes laterally from the column portion 226 of the column member 210 and radially inward relative to substrates, e.g., the substrate 2 (shown in FIG. 1), supported within the substrate storage rack 200. In certain examples, the seating portion 228 may be a first seating portion 228, and the column member 210 may have one or more second seating portions 234. In such examples, the second seating portion 234 may protrude laterally from the column portion 226 of the column member 210, may be spaced apart from the first seating portion 228 along the longitudinal length of the column member 210, and may be one of only two (2) seating portions arranged along the longitudinal length 232 of the column member 210. It is also contemplated that the first seating portion 228 and the second seating portion 234 may be two (2) of twenty-five (25) seating portions, or thirty-one (31) seating portions spaced apart from one another along the longitudinal length 232 of the column member 210. However, as will be appreciated by those of skill in the art in view of the present disclosure, the column member 210 may have fewer or more seating portions than shown and described herein and remain within the scope of the present disclosure.

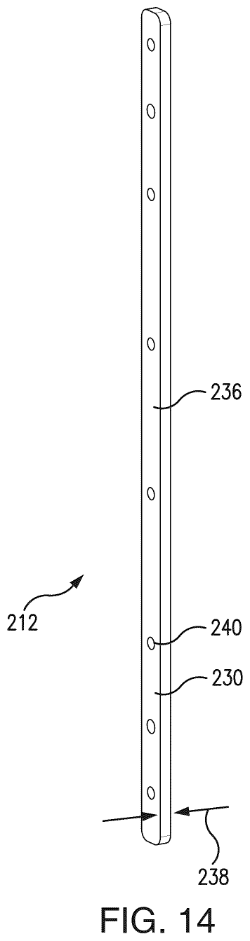

Referring to FIG. 14, the spacer member 212 includes a spacer member plate body 236 with a thickness 238 and a plurality of fastener apertures 240 extending through the spacer member plate body 236. The plurality of fastener apertures 240 are longitudinally spaced apart from one another along the spacer member axis 216. In the illustrated example, the spacer member 212 has eight (8) fastener apertures 240. As will be appreciated by those of skill in the art in view of the present disclosure, the spacer member 212 may have fewer or additional fastener apertures 240 and remain within the scope of the present disclosure.

The spacer member plate body 236 may be formed from a metallic material 242, such as an aluminum-containing alloy or stainless-steel material, and may be the same as the metallic material 230 forming the column member plate body 222. In certain examples, the thickness 238 of the spacer member plate body 236 may be smaller than the diameter of the ball member 156. For example, the thickness 238 of the spacer member plate body 236 may be less than 4 millimeters, or less than 3 millimeters, or even less than 2 millimeters. It is also contemplated that, in accordance with certain examples, the thickness 238 of the spacer member plate body 236 may be greater than the thickness 107 (shown in FIG. 9) of the clamp member sheet body 101 (shown in FIG. 8) of the clamp member 154. In certain examples, the thickness 238 of the spacer member plate body 236 may be greater than the thickness 166 (shown in FIG. 6) of the column member sheet body 158 (shown in FIG. 5). For example, the thickness 238 may be between about 2 millimeters and about 20 millimeters, or between about 2 millimeters and about 15 millimeters, or even between about 2 millimeters and about 10 millimeters. In certain examples, the thickness 238 may be about 3 millimeters. As will be appreciated by those of skill in the art in view of present disclosure, thicknesses within the ranges can simplify assembly of the fabrication of the column assembly 202, for example, by controlling magnitude of the tangential clamping force 220 (shown in FIG. 11) according selection of thickness 238 of the spacer member plate body 236 and the diameter of the ball member 156.

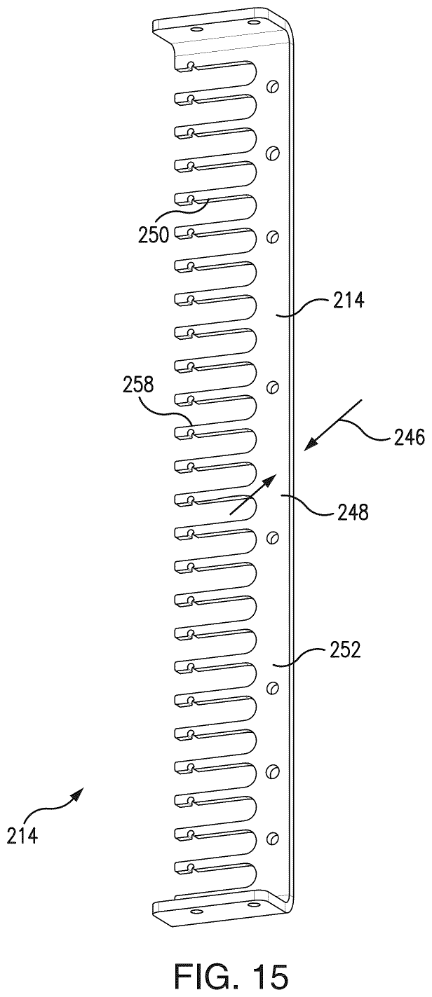

Referring to FIG. 15, the clamp member 214 includes a clamp member plate body 244 with a thickness 246, a base portion 248, and a clamping portion 250. The clamp member plate body 244 may be formed from a metallic material 252, such as an aluminum-containing alloy or stainless steel, like 4040 aluminum or 304 stainless steel, respectively. In certain examples, the metallic material 252 may be the same as the metallic material 230 forming the column member plate body 222 and/or the metallic material 230 forming the spacer member plate body 236.

The thickness 246 may be greater than the thickness 107 (shown in FIG. 9) of the clamp member sheet body 101 (shown in FIG. 8), or greater than the thickness 166 (shown in FIG. 6) of the column member sheet body 158 (shown in FIG. 5). For example, the thickness 246 may be between about 2 millimeters and about 20 millimeters, or between about 2 millimeters and about 15 millimeters, or even between about 2 millimeters and about 10 millimeters. The thickness 224 of the clamp member plate body 244 may be about 3 millimeters. In certain examples, the thickness 246 may be or substantially equivalent to the thickness 224 (shown in FIG. 13) of the column member plate body 222 (shown in FIG. 13) and/or the thickness 238 (shown in FIG. 14) of the spacer member plate body 236 (shown in FIG. 14). As will be appreciated by those of skill in the art in view of present disclosure, matching thickness of the clamp member plate body 244 to the column member plate body 222 can limit deformation in one the seating portion 228 and the clamping portion 250 responsive to the tangential clamping force 220 exerted on the ball member 156 during assembly of the column assembly 202 (shown in FIG. 10), simplifying assembly of the column assembly 202.

The base portion 248 of the column member 210 has a longitudinal length 254. In certain examples, the longitudinal length 254 may be substantially equivalent to the longitudinal length 232 of the column portion 226 (shown in FIG. 13) of the column member 210 (shown in FIG. 11). The clamping portion 250 of the clamp member 214 protrudes laterally from the base portion 248 of the column member 210. It is contemplated that the clamping portion 250 circumferentially may overlap the seating portion 228 of the column member 210, the clamping portion 250 extending radially inward in this respect relative to substrates, e.g., the substrate 2 (shown in FIG. 1), supported within the substrate storage rack 100.

In certain examples, the clamping portion 250 may be a first clamping portion 250, and the clamp member 214 may have one or more second clamping portions 258. In such examples, the second clamping portion 258 may protrude laterally from the clamping portion 250 of the clamp member 214, may be spaced apart from the first clamping portion 256 along the longitudinal length 254 of the clamp member 214, and may be one of only two (2) clamping portions arranged along the longitudinal length 254 of the clamp member 214. In certain examples, the first clamping portion 256 and the second clamping portion 258 may be two (2) of twenty-five (25) seating portions, or thirty-one (31) seating portions spaced apart from one another along the longitudinal length 254 of the clamp member 214. It is also contemplated that, in accordance with certain examples, both the clamp member 214 and the column member 210 may have identical numbers of clamping portions and the seating portions. As will be appreciated by those of skill in the art in view of the present disclosure, forming the clamp member 214 and the column member 210 with the same number clamping and seating portions can simplify fabrication of the column assembly 202, for example, by limiting the number of detail parts included in the assembly and/or error-proofing the assembly. It is further contemplated that the seating portion the seating portion 228 and the clamping portion 250 may have a first longitudinal slot 260 (shown in FIG. 11) and a tangentially opposed second longitudinal slot 262 (shown in FIG. 11) seating where there is the ball member 156. As above, this simplifies the assembly of the column assembly 202 as the ball member 156 may be registered and thereafter maintained in one of the first longitudinal slot 260 and the second longitudinal slot 262, and thereafter clamped therein by force exerted about the other of the first longitudinal slot 260 and the second longitudinal slot 262 as the clamp member 214 is fastened to the column member 210.

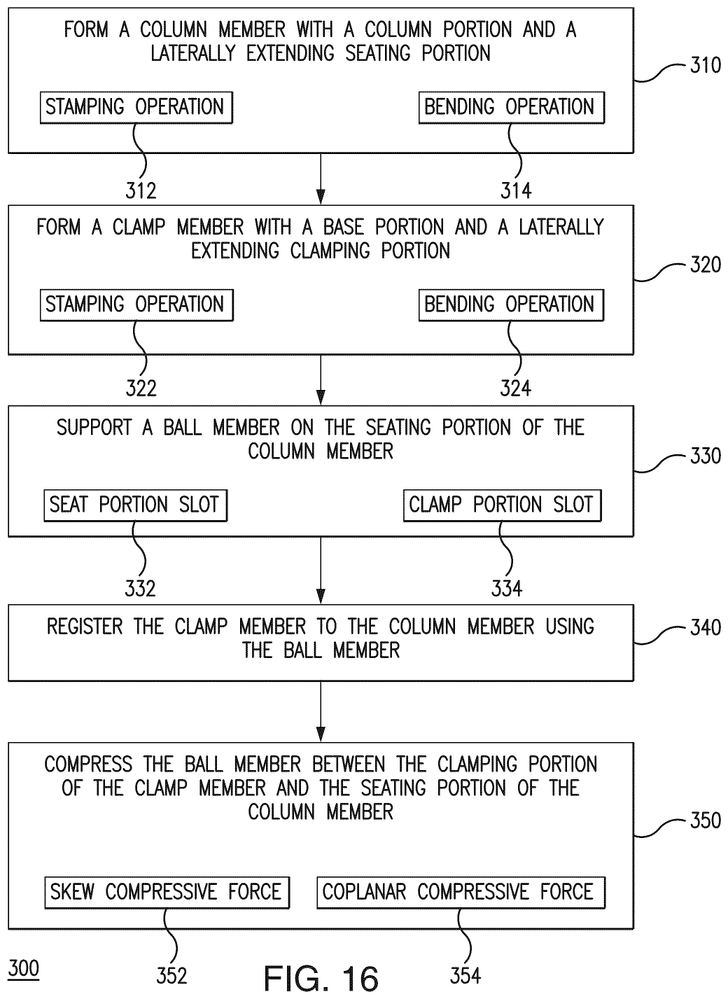

With reference to FIG. 16, a method 300 of making a substrate storage rack, e.g., the substrate storage rack 100 (shown in FIG. 1), is shown. As shown with box 310, a column member, e.g., the column member 152 (shown in FIG. 3), is formed having a column portion, e.g., the column portion 160 (shown in FIG. 3), and a seating portion, e.g., the seating portion 162 (shown in FIG. 3), extending laterally from the column portion of the column member. In certain examples, the column member may be formed using a stamping operation, as shown with box 312. For example, the column member may be stamped from sheet stock, e.g., the column member sheet body 158 (shown in FIG. 5). In accordance with certain examples, the column member may be formed using a bending operation, for example, by bending the column member sheet body that a first column portion, e.g., the first column portion 160 (shown in FIG. 5), and a second column portion, e.g., the second column portion 178 (shown in FIG. 5), extend in parallel with one another on opposite sides of a column member axis, e.g., the column member axis 168 (shown in FIG. 6), as shown with box 314.

As shown with box 320, a clamp member, e.g., the clamp member 154 (shown in FIG. 3), is formed having a base portion, e.g., the base portion 103 (shown in FIG. 8), and a clamping portion, e.g., the clamping portion 198 (shown in FIG. 8), extending laterally from the base portion of the clamp. In certain examples, the clamp member may also be formed using a stamping operation, as shown with box 322. In this respect the clamp member may also be stamped from sheet stock, e.g., the clamp member sheet body 101 (shown in FIG. 8). In accordance with certain examples, the clamp member may be formed using a bending operation, for example, by bending the clamp member sheet body such that a first base portion, e.g., the first base portion 103 (shown in FIG. 8), and a second base portion, e.g., the second base portion 111 (shown in FIG. A), extend in parallel with one another.

As shown with box 330, a ball member, e.g., the ball member 156 (shown in FIG. 3), is supported on the seating portion of the column member. In certain examples, the ball member may be supported on a longitudinal slot defined by the seating portion of the column member, e.g., the longitudinal slot 188 (shown in FIG. 5), as shown with box 332. In accordance with certain example, the ball member may be supported on a longitudinal slot defined by the clamping portion of the clamp member, e.g., the clamping portion longitudinal slot 208 (shown in FIG. 10). It is contemplated that the longitudinal slot maintains position of the ball member relative to at least one of the column members and the clamp member such that the clamp member may be registered to the column member using the ball member, as shown with box 340.

As shown with box 350, the ball member is thereafter compressed between the clamping portion of the clamp member and the seating portion of the column member. In certain examples, the ball member may be fixed between the clamping portion and the seating portion by a radial clamping force exerted on the ball member by the seating portion and the clamping, the radial clamping force intersecting the column member axis, as shown with box 352. In accordance with certain examples, the ball member may be fixed between the clamping portion and the seating portion by a tangential clamping force exerted by the seating member and the clamp member on the ball member, the tangential clamping force not intersecting a spacer member axis within the column assembly, as shown with box 354. It is contemplated that the clamp member be fastened to the column member while exerting the clamping force on the ball member, the ball member thereby being compressive fixed within the column assembly between the seating portion of the column member and the clamping portion of the clamp member.

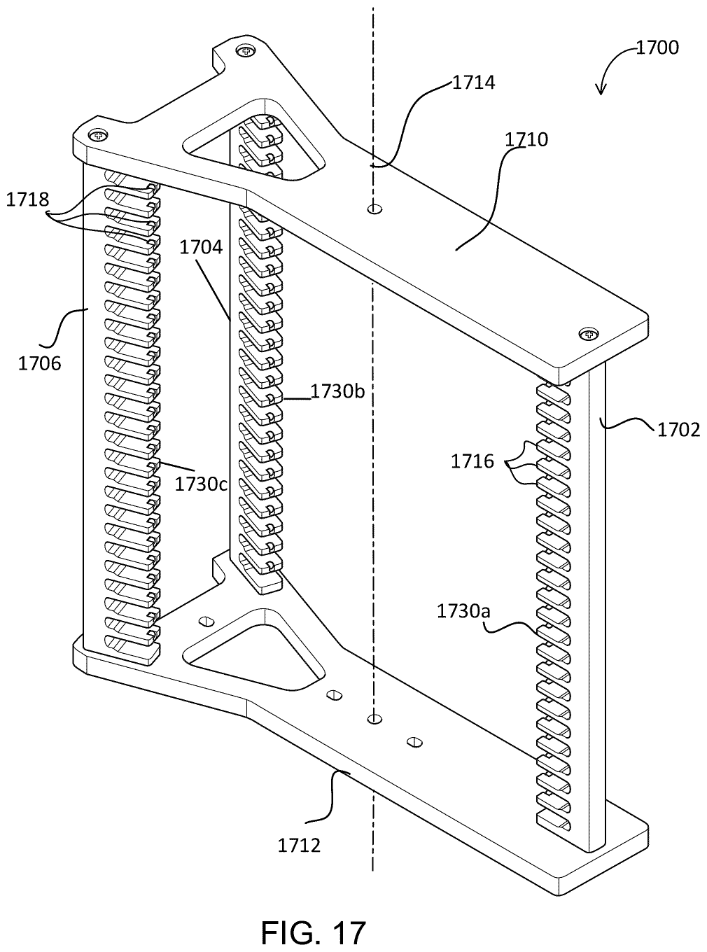

Referring to FIG. 17, another example substrate storage rack 1700 is shown. The example substrate storage rack 1700 may be placed or supported within the front-end enclosure 20, the pod 26, the load lock chamber 24, and/or any other locations in the semiconductor processing system. The substrate storage rack 1700 may be configured to support a plurality of substrates. In exemplary embodiments, the base material used to manufacture the substrate storage rack 1700 may comprise metal matrix composites, carbon, aluminum (e.g., aluminum nitride), titanium, stainless steel, nickel-plated aluminum, quartz, and/or ceramics. In exemplary embodiments, other base materials having the desired quality may be used for manufacturing the substrate storage rack 1700. The substrate storage rack 1700 may include three column assemblies 1702, 1704, and 1706. In exemplary embodiments, the column assemblies 1702, 1704, and 1706 may be substantially the same in all respects. The length of the column assemblies 1702, 1704, and 1706 may be in the range of 200 to 1000 millimeters. The substrate storage rack 1700 may further include a top plate 1710 and a bottom plate 1712 that support the column assemblies 1702, 1704, and 1706. In other words, as shown in FIG. 17, the top plate 1710 and the bottom plate 1712 may be separated from each other by vertical placement of the column assemblies 1702, 1704, and 1706 parallel to a central axis 1714.

Each of the column assemblies 1702, 1704, and 1706 may define one or more protrusion elements 1716. In exemplary embodiments, each column assembly 1702, 1704, and 1706 may include n number of protrusion elements (e.g., n=25, 50, 100, 200, etc.). Three protrusion elements, respectively extending from column assemblies 1702, 1704, and 1706, may be aligned in a common horizontal plane to collectively define a slot for supporting a substrate. For example, the protrusion elements 1730a, 1730b, and 1730c from the column assemblies 1702, 1704, and 1706, respectively, may be aligned to collectively define a slot for supporting a substrate.

In the illustrated example in FIG. 17, the substrate storage rack 1700 may include multiple column assemblies 1702, 1704, and 1706. Each column assembly may have a similar structure, with the assemblies extending in parallel to one another and positioned in an offset arrangement to provide support for substrates. In the illustrated example in FIG. 17, the column assemblies 1702, 1704, and 1706 may be separated from each other by less than about 300 millimeters. In accordance with certain examples, the column assembly 1702 may be offset from both the column assemblies 1704 and 1706 by more than 90 degrees from the central axis 1714 of the substrate storage rack 1700. The column assemblies 1704 and 1706 may be offset by less than 90 degrees from the central axis 1714. The column assemblies 1702, 1704, and 1706 may form three corners of an acute isosceles triangle. A substrate may be transferred into or out of the substrate storage rack 1700 by using the opening between the column assembly 1702 and the column assembly 1704. Additionally, or alternatively, a substrate may be transferred into or out of the substrate storage rack 1700 by using the opening between the column assembly 1702 and the column assembly 1706.

In exemplary embodiments, the body of the substrate storage rack 1700 (e.g., including the top plate 1710, the bottom plate 1712, the column assemblies 1702, 1704, 1706) may advantageously be made of a base material, such as metal matrix composites, carbon, aluminum (for example aluminum nitride), titanium, stainless steel, nickel-plated aluminum, quartz, and/or ceramics. The body of the substrate storage rack 1700 made of the base material may be provided with a coating, such as an electroless nickel plating, electrolytic nickel plating, nickel-phosphorus plating, nickel-boron plating, chromium plating, cobalt-based plating, carbide coatings (e.g., silicon carbide, tantalum carbide, titanium, tungsten carbide, chromium carbide, etc.), or any other suitable coating. The coating of the substrate storage rack 100 may have a thickness in the range from about 0.5 nm to about 50 nm, and in some embodiments from about 1 nm to about 20 nm.

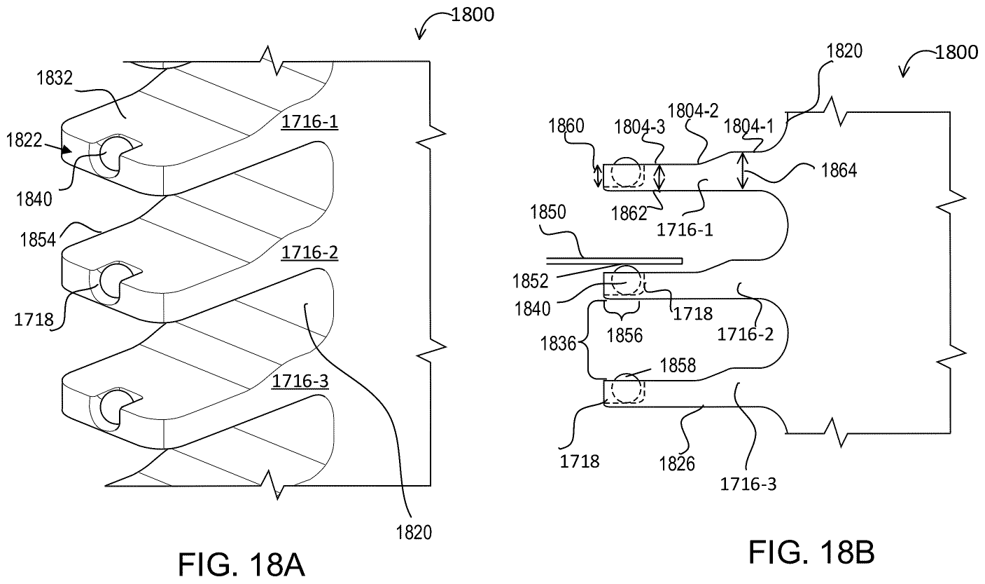

The protrusion elements 1716 of the column assemblies 1702, 1704, and 1706 may have openings 1718 on the top surface of the protrusion elements 1716 (1716-1, 1716-2, 1716-3), as shown in more detail in FIGS. 18A and 18B. For ease of description, elements 1716-1, 1716-2, and 1716-3 may be collectively referred to as element 1716. FIG. 18A is a perspective view of a portion of a column assembly 1800 (e.g., any one of the column assemblies 1702, 1704, and 1706) of the substrate storage rack 1700 of FIG. 17, while FIG. 18B is a side view of the portion of the column assembly. The top surface 1832 of a protrusion element 1716 may include an opening 1718 that does not extend entirely through the protrusion element 1716. For example, in the example substrate storage rack 1700 and as shown in more detail in FIGS. 18A and 18B, an opening 1718 may be formed at the side surface 1822 of the top surface 1832 of each of the protrusion elements 1716-1, 1716-2, and 1716-3, thereby defining a recess, a notch, or a pocket that partially intersects the perimeter 1854 of the protrusion elements 1716-1, 1716-2, and 1716-3. The opening 1718 may be configured to provide seating, support, or retention of a ball member 1840 (as shown in FIGS. 18A and 18B, with FIG. 18B including outlines for the openings 1718 and the ball members 1840). As shown in FIG. 18A, the column assembly 1800 may include an inner surface 1820 and a plurality of protrusion elements 1716-1, 1716-2, and 1716-3 that protrude out of the inner surface 1820 of column assembly 1800.

Referring to FIGS. 18A and 18B, the ball member 1840 may be seated on the seating portion 1856 of the protrusion element 1716. The seating portion 1856 may be the exposed surface of the opening 1718. The ball members 1840 may be fixed to the seating portion 1856 of the protrusion element 1716. A protruding portion 1858 of the ball member 1840 may protrude from the opening 1718. For example, the protruding portion 1858 may protrude 1 to 6 millimeters above the top surface 1832 of the protrusion element 1716. The opening 1718 may have a depth that is smaller than a diameter of the ball member 1840.

The ball member 1840 may be formed from a ceramic material. For example, the ball member material may include silicon nitride, silicon carbide, zinc oxide, aluminum oxide, and/or quartz. In accordance with certain examples, the ball member material may consist of or consist essentially of a ceramic material, silicon nitride (Si3N4), zinc oxide (ZnO3), aluminum oxide (Al2O3), or quartz. Examples of suitable ball members include G5 silicon nitride ceramic ball bearings, available from BC Precision of Chattanooga, Tenn. The ball member 1840 may also have a diameter that is between about 1 millimeter and 10 millimeters, or between 2 millimeters and about 8 millimeters, or even between about 3 millimeters and about 6 millimeters. As will be appreciated by those of skill in the art, diameters within these ranges allow the ball member 1840 to protrude in part above both the seating portion 1856. Protrusion above the seating portion 1856 may allow the ball member 1840 to support a substrate 1850, the substrate 2 (shown in FIG. 1), with sufficient distance to avoid contact between the underside of the substrate and the top surface 1832 of the protrusion element 1716. As shown in FIG. 18B, only the ball member 1840 is in direct contact 1852 with the substrate 1850. The substrate 1850 may be supported by the ball member 1840. The substrate 1850 may rest on the protruding portion 1858 of the ball member 1840. As will be appreciated by those of the skill in the art in view of the present disclosure, avoiding contact allows the base material forming the substrate storage rack 1700 and the protrusion elements 1716 to limit contamination of the substrates within the semiconductor processing system 10 by the base material of the protrusion elements 1716.

As shown in FIGS. 18A and 18B, each protrusion element 1716 may include a top surface 1832, a side surface 1822 and a bottom surface 1826. In exemplary embodiments, the bottom surface 1826 and the top surface 1832 may extend from the inner surface 1820 of the column assembly 1800. The protrusion element 1716 includes a first flat portion 1804-1 coupled to an inner surface 1820, a slanted portion 1804-2 coupled to the first flat portion 1804-1, and a second flat portion 1804-3 coupled to the slanted portion 1804-2. The thickness 1862 of the second flat portion 1804-3 may be smaller than the thickness 1864 of the first flat portion 1801-1. The thickness 1862 of the second flat portion 1804-3 may be in the range of 2 to 5 millimeters, and the thickness 1864 of the first flat portion 1801-1 may be in the range of 2.5 to 11 millimeters. In some embodiments, the difference in the thicknesses 1862 and 1864 may be in the range of 0.5 to 6 millimeters. The second flat portion 1804-3 may comprise the opening 1718 of the protrusion element 1716.

The top surface 1832 and the bottom surface 1826 may be separated by a side surface 1822. In exemplary embodiments, the side surface 1822 may measure 2-10 millimeters, while the depth 1860 of the opening 1718 may measure 1-9 millimeters. In exemplary embodiments, the bottom surface 1826 measures 10-25 mm. That is, the protrusion elements 1716 may extend out 10-25 mm. Further, in exemplary embodiments, the distance 1836 may be defined as the space between the bottom surface 1826 of a first protrusion element of column assembly 1800 (such as 1716-2) and a top surface 1832 of the next protrusion element of column assembly 1800 (such as 1716-3) and may measure in the range of 5-20 mm.

In some embodiments, the openings 1718 in protrusion elements 1716 may also be positioned in different regions of the top surfaces of the protrusion elements. In some embodiments, the openings may be located proximate to, but spaced inward from, the edge of the top surface of the protrusion elements. In some embodiments, the openings may be disposed away from the edge and may take the form of a recess, a blind hole, a dimple, or a socket on the top surface. These variations in position and geometry allow the opening to provide seating, support, or retention of a ball member.

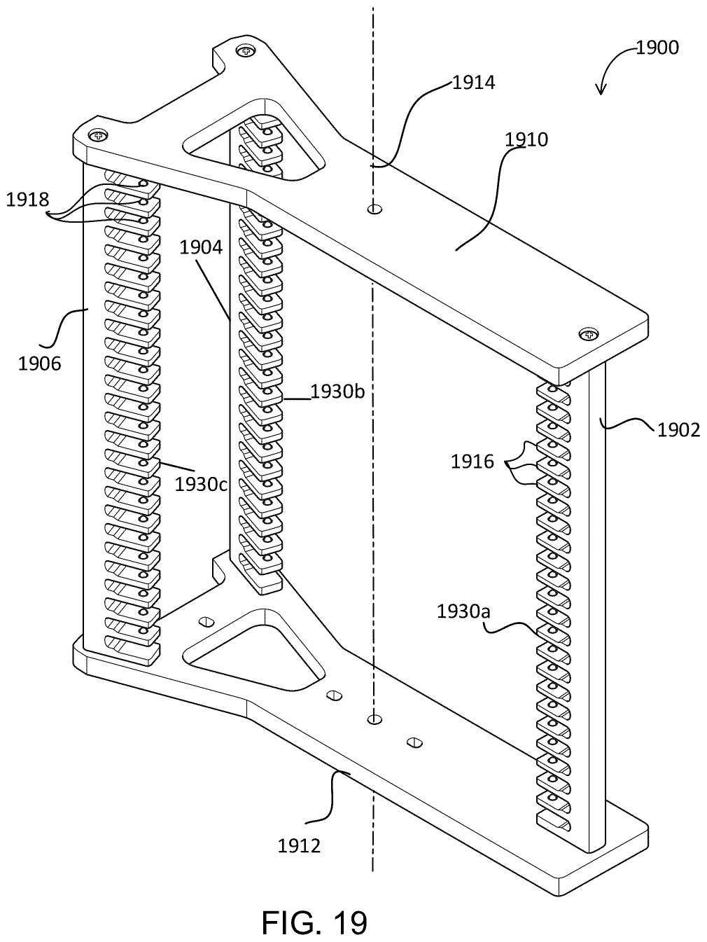

For example, FIG. 19 illustrates another example substrate storage rack 1900. The example substrate storage rack 1900 may be placed or supported within the front-end enclosure 20, the pod 26, the load lock chamber 24, and/or any other locations in the semiconductor processing system. The substrate storage rack 1900 may be similar to the substrate storage racks 1700 and include the three column assemblies 1902, 1904, and 1906, the top plate 1910, and the bottom plate 1912. In accordance with certain examples, the column assembly 1902 may be offset from both the column assemblies 1904 and 1906 by more than 90 degrees from the central axis 1914 of the substrate storage rack 1900. The column assemblies 1904 and 1906 may be offset by less than 90 degrees from the central axis 1914. The column assemblies 1902, 1904, and 1906 may form three corners of an acute isosceles triangle.

Each of the column assemblies 1902, 1904, and 1906 may define one or more protrusion elements 1916. The protrusion elements 1916 may comprise openings 1918 that are disposed away from the edge of the protrusion elements 1916.

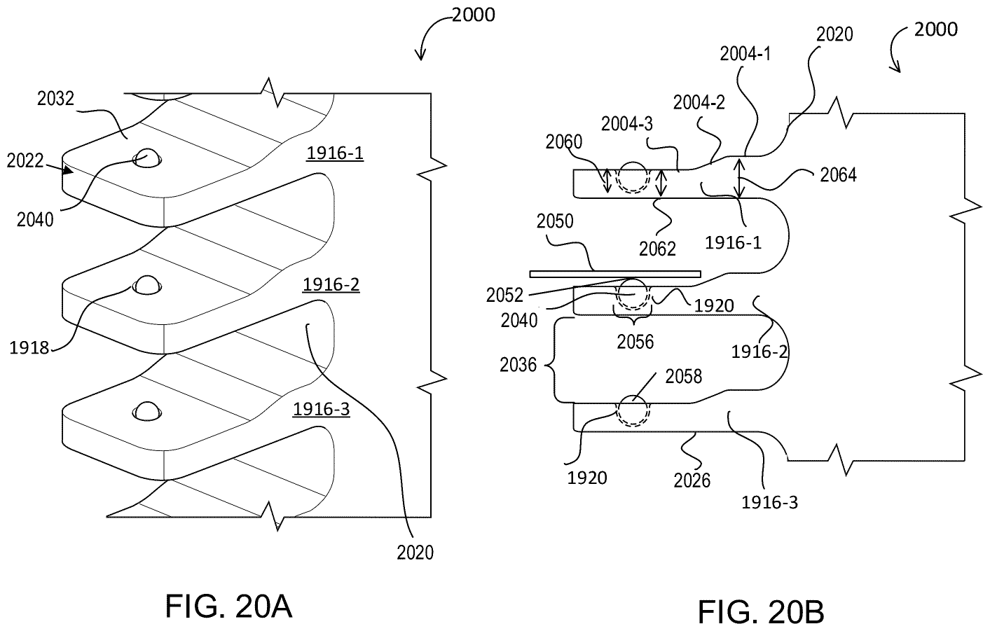

The protrusion elements 1916 of the column assemblies 1902, 1904, and 1906 may have openings 1918 on the top surface 2032 of the protrusion elements 1916 (1916-1, 1916-2, 1916-3) as shown in more detail in FIGS. 20A and 20B. For ease of description, elements 1916-1, 1916-2, and 1916-3 may be collectively referred to as element 1916. The openings 1918 may be a blind hole, a recess, a cavity, or a depression, and away from the side surface 2022 of the protrusion element 1916. FIG. 20A is a perspective view of a portion of a column assembly 2000 (e.g., any one of the column assemblies 1902, 1904, and 1906) of the substrate storage rack 1900 of FIG. 19, while FIG. 20B is a side view of the portion of the column assembly. The top surface 2032 of a protrusion element 1916 may include an opening 1918 that does not extend entirely through the protrusion element 1916. For example, in the example substrate storage rack 1900 and as shown in more detail in FIGS. 20A and 20B, an opening 1918 is on the top surface 2032 of each of the protrusion elements 1916-1, 1916-2, and 1916-3. The opening 1918 may be configured to provide seating, support, or retention of a ball member 2040 (as shown in FIGS. 20A and 20B, with FIG. 20B including outlines for the openings 1918 and the ball members 2040). As shown in FIG. 20A, the column assembly 2000 may include an inner surface 2020 and a plurality of protrusion elements 1916-1, 1916-2, and 1916-3 that protrude out of the inner surface 2020 of column assembly 2000.

Referring to FIGS. 20A and 20B, the ball member 2040 may be seated on the seating portion 2056 of the protrusion element 1916. The ball members 2040 may be fixed to the seating portion 2056 of the protrusion element 1916. A protruding portion 2058 of the ball member 2040 may protrude from the opening 1918. For example, the protruding portion 2058 may protrude 1 to 6 millimeters above the top surface 2032 of the protrusion element 1916. The opening 1918 may have a depth 2060 that is smaller than a diameter of the ball member 2040.

The ball member 2040 may be formed from a ceramic material. For example, the ball member material may include silicon nitride, silicon carbide, zinc oxide, aluminum oxide, and/or quartz. In accordance with certain examples, the ball member material may consist of or consist essentially of a ceramic material, silicon nitride (Si3N4), zinc oxide (ZnO3), aluminum oxide (Al2O3), or quartz. Examples of suitable ball members include G5 silicon nitride ceramic ball bearings, available from BC Precision of Chattanooga, Tenn. The ball member 2040 may also have a diameter that is between about 1 millimeter and 10 millimeters, or between 2 millimeters and about 8 millimeters, or even between about 3 millimeters and about 6 millimeters. As will be appreciated by those of skill in the art, diameters within these ranges allow the ball member 2040 to protrude in part above both the seating portion 2056. Protrusion above the seating portion 2056 may allow the ball member 2040 to support a substrate 2050, the substrate 2 (shown in FIG. 1), with sufficient distance to avoid contact between the underside of the substrate and the top surface 2032 of the protrusion element 1916. As shown in FIG. 20B, only the ball member 2040 may be in direct contact 2052 with the substrate 2050. The substrate 2050 may be supported by the ball member 2040. The substrate 2050 may rest on the protruding portion 2058 of the ball member 2040. As will be appreciated by those of the skill in the art in view of the present disclosure, avoiding contact allows the base material forming the substrate storage rack 1900 and the protrusion elements 1916 to limit contamination of the substrates within the semiconductor processing system 10 by the base material of the protrusion elements 1916.

As shown in FIGS. 20A and 20B, each protrusion element 1916 may include a top surface 2032, a side surface 2022 and a bottom surface 2026. In exemplary embodiments, the bottom surface 2026 and the top surface 2032 may extend from the inner surface 2020 of the column assembly 2000. The protrusion element 1916 includes a first flat portion 2004-1 coupled to an inner surface 2020, a slanted portion 2004-2 coupled to the first flat portion 2004-1, and a second flat portion 2004-3 coupled to the slanted portion 2004-2. The thickness 2062 of the second flat portion 2004-3 may be smaller than the thickness 2064 of the first flat portion 2001-1. The thickness 2062 of the second flat portion 2004-3 may be in the range of 2 to 5 millimeters, and the thickness 2064 of the first flat portion 2001-1 may be in the 2.5 to 11 millimeters. In some embodiments, the difference in the thicknesses 2062 and 2064 may be in the range of 0.5 to 6 millimeters. The second flat portion 2004-3 may comprise the opening 1918 of the protrusion element 1916.

The top surface 2032 and the bottom surface 2026 may be separated by a side surface 2022. In exemplary embodiments, the side surface 2022 may measure 2-10 millimeters, while the depth 2060 of the opening 1918 may measure 1-9 millimeters. In exemplary embodiments, the bottom surface 2026 measures 10-25 mm. That is, the protrusion elements 1916 may extend out 10-25 mm. Further, in exemplary embodiments, the distance 2036 may be defined as the space between the bottom surface 2026 of a first protrusion element of column assembly 2000 (such as 1916-2) and a top surface of the next protrusion element of column assembly 2000 (such as 1916-3) and may measure in the range of 5-20 mm.

Example substrate storage racks described herein comprise ball members having a generally spherical shape. However, ball members of other shapes (e.g., a cube, a cylinder, a cone, or a polyhedron) may be used in the substrate storage racks described herein. The openings of the top surfaces of the protrusion elements may be selectively configured in shape, contour, or dimension to receive and support at least a portion of a non-spherical ball member.

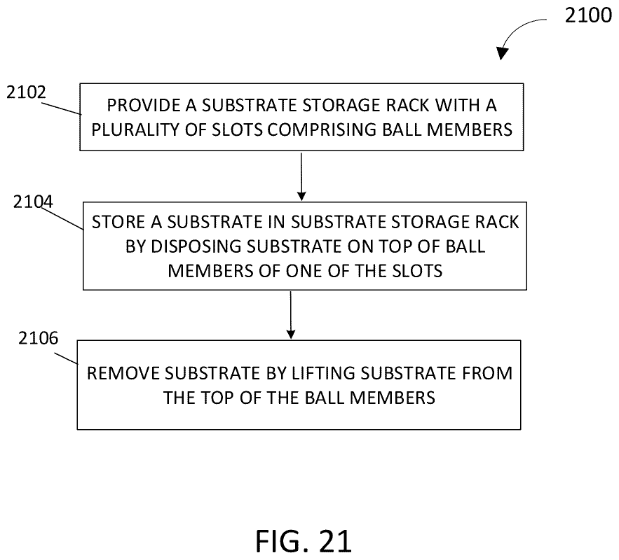

With reference to FIG. 21, a method 2100 of storing and handling substrates in a substrate storage rack (e.g., the substrate storage rack 100 in FIG. 2, the substrate storage rack 200 in FIG. 10, the substrate storage rack 1700 in FIG. 17, or the substrate storage rack 1900 in FIG. 19) is shown. The example steps in FIG. 21 may be performed in different orders and with different, fewer, or additional steps than those illustrated. Some steps may be omitted, while multiple steps may be combined. The method 2100 may be implemented in environments such as semiconductor fabrication facilities, substrate transport modules, or cleanroom storage systems, where mechanical precision and contamination control are critical.

At step 2102, the method includes providing a substrate storage rack comprising a plurality of slots. For example, the protrusion elements 1730a, 1730b, and 1730c from the column assemblies 1702, 1704, and 1706 in FIG. 17, respectively, may be aligned to collectively define a slot for supporting a substrate in the substrate storage rack 1900. As another example, the protrusion elements 1930a, 1930b, and 1930c from the column assemblies 1902, 1904, and 1906 in FIG. 19, respectively, may be aligned to collectively define a slot for supporting a substrate in the substrate storage rack 1900. Each slot may be configured to receive and support a respective substrate.

In the illustrated embodiments, each slot comprises a plurality of protrusion elements (e.g., protrusion elements 1730a, 1730b, 1730c, 1930a, 1930b, and 1930c) and a plurality of ball members (e.g., ball members 1830, 2040). Each protrusion element includes a top surface (e.g., top surfaces 1832, 2032) with an opening (e.g., openings 1718, 1918) configured to support a ball member. In some examples, the opening may be a blind hole, a recess, a cavity, or a depression, and away from the side surface of the protrusion element. In other examples, the opening may be a recess at or near an edge of the protrusion element.

Proceeding to step 2104, the method may include storing a substrate in the substrate storage rack by disposing the substrate (e.g., the substrate 1850, 2050) on top of the plurality of ball members (e.g., 1840, 2040) of one of the plurality of slots. The ball members are arranged to uniformly support the underside of the substrate while minimizing the surface area of the substrate that is in contact with the ball members. In some embodiments, the substrate may be only in direct contact with the ball members, and not with the protrusion elements or any other structural features of the substrate storage rack. This exclusive contact configuration may provide a mechanically stable yet contamination-minimizing support that is suitable for particle-sensitive substrates. The positioning and shape of the openings may ensure that the ball members remain fixed during loading and unloading. At step 2106, the method may include removing the substrate from the substrate storage rack by lifting the substrate from the top of the ball members.

Steps 2104 and/or 2106 may be performed manually, by a front-end transfer robot (e.g., front-end transfer robot 28), and/or by a back-end transfer robot (e.g., back-end transfer robot 34). Because the substrate is only supported by ball members and not gripped or clamped, inserting and removal of the substrate may be smooth and non-abrasive, reducing the likelihood of particle shedding or mechanical damage.

In various embodiments, the ball members may be formed of materials having high mechanical durability and low contamination potential, such as silicon nitride (Si₃N₄), silicon carbide (SiC), zinc oxide (ZnO), aluminum oxide (Al₂O₃), and quartz (SiO₂). These materials are particularly well-suited for use in semiconductor manufacturing environments due to their resistance to thermal expansion, chemical corrosion, and mechanical wear.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A substrate storage rack comprising:
a bottom plate;
a top plate spaced apart from the bottom plate;
at least one column assembly connecting the top plate to the bottom plate and comprising a plurality of protrusion elements; and
a plurality of ball members,
wherein each protrusion element, of the plurality of protrusion elements, comprises a top surface with an opening configured to support a corresponding ball member of the plurality of ball members; and
wherein the corresponding ball member of each protrusion element of the plurality of protrusion elements:
protrudes from the top surface of the protrusion element in a direction toward the top plate; and
is configured to support a substrate within the substrate storage rack.

2. The substrate storage rack of claim 1, wherein the substrate, supported by the corresponding ball member, is only in direct contact with the corresponding ball member.

3. The substrate storage rack of claim 1, wherein the opening, of each protrusion element of the plurality of protrusion elements, comprises a recess on the top surface of the protrusion element.

4. The substrate storage rack of claim 1, wherein the opening, of each protrusion element of the plurality of protrusion elements, comprises a recess at or near an edge of the protrusion element.

5. The substrate storage rack of claim 1, wherein the corresponding ball member, of each protrusion element of the plurality of protrusion elements, protrudes 1 to 6 millimeters above the top surface of the protrusion element.

6. The substrate storage rack of claim 1, wherein the plurality of ball members comprise a ceramic material.

7. The substrate storage rack of claim 1, wherein the plurality of ball members comprise silicon nitride, silicon carbide, zinc oxide, aluminum oxide, and/or quartz.

8. The substrate storage rack of claim 1, wherein each of the plurality of ball members has a diameter that is from 2 to 8 millimeters.

9. The substrate storage rack of claim 1, wherein the at least one column assembly comprises a column portion extending longitudinally between the bottom plate and the top plate; and
wherein the plurality of protrusion elements extend laterally from the column portion.

10. The substrate storage rack of claim 1, wherein the plurality of ball members are longitudinally spaced apart along a longitudinal length of the at least one column assembly.

11. The substrate storage rack of claim 1, wherein the plurality of protrusion elements comprise quartz, ceramic, carbon, aluminum, stainless steel, and/or titanium.

12. The substrate storage rack of claim 1, wherein each protrusion element of the plurality of protrusion elements comprises:
a base material comprising aluminum; and
an electroless nickel plating disposed on at least a portion of the base material.

13. The substrate storage rack of claim 1, wherein the at least one column assembly comprises an inner surface and an outer surface; and
wherein the plurality of protrusion elements extend from the inner surface.

14. The substrate storage rack of claim 13, wherein each protrusion element of the plurality of protrusion elements comprises:
a first flat portion coupled to the inner surface;
a slanted portion coupled to the first flat portion; and
a second flat portion:
coupled to the slanted portion;
thinner than the first flat portion; and
comprising the opening of the protrusion element.

15. The substrate storage rack of claim 1, wherein the at least one column assembly comprises a first column assembly, a second column assembly, and a third column assembly; and
wherein the first column assembly, the second column assembly, and the third column assembly form an obtuse isosceles triangle.

16. The substrate storage rack of claim 1, wherein the at least one column assembly comprises a first column assembly, a second column assembly, and a third column assembly; and
wherein the first column assembly, the second column assembly, and the third column assembly form an acute isosceles triangle.

17. A load lock chamber of a semiconductor processing system comprising:
at least one substrate storage rack comprising a bottom plate, a top plate spaced apart from the bottom plate, at least one column assembly connecting the top plate to the bottom plate, and a plurality of ball members,
wherein the at least one column assembly comprises a plurality of protrusion elements;
wherein each protrusion element, of the plurality of protrusion elements, comprises a top surface with an opening configured to support a corresponding ball member of the plurality of ball members; and
wherein the corresponding ball member of each protrusion element of the plurality of protrusion elements:
protrudes from the top surface of the protrusion element in a direction toward the top plate; and
is configured to support a substrate within the substrate storage rack.

18. The load lock chamber of claim 17, wherein the substrate, supported by the corresponding ball member, is only in direct contact with the corresponding ball member.

19. An equipment front end module of a semiconductor processing system comprising:
at least one substrate storage rack comprising a bottom plate, a top plate spaced apart from the bottom plate, at least one column assembly connecting the top plate to the bottom plate, and a plurality of ball members,
wherein the at least one column assembly comprises a plurality of protrusion elements;
wherein each protrusion element, of the plurality of protrusion elements, comprises a top surface with an opening configured to support a corresponding ball member of the plurality of ball members; and
wherein the corresponding ball member of each protrusion element of the plurality of protrusion elements:
protrudes from the top surface of the protrusion element in a direction toward the top plate; and
is configured to support a substrate within the substrate storage rack.

20. The equipment front end module of claim 19, wherein the substrate, supported by the corresponding ball member, is only in direct contact with the corresponding ball member.

21. A method comprising:
providing a substrate storage rack comprising a plurality of slots for storing substrates, wherein each of the plurality of slots comprises:
a plurality of protrusion elements; and
a plurality of ball members, wherein each protrusion element of the plurality of protrusion elements comprises a top surface with an opening configured to support a corresponding ball member of the plurality of ball members; and
storing a substrate in the substrate storage rack by disposing the substrate on top of the plurality of ball members of one of the plurality of slots.

22. The method of claim 21, further comprising:
removing the substrate from the substrate storage rack by lifting the substrate from the top of the plurality of ball members of the one of the plurality of slots.

23. The method of claim 21, wherein during the storing of the substrate in the substrate storage rack, the substrate is only in direct contact with the plurality of ball members of the one of the plurality of slots.

24. The method of claim 21, wherein the opening, of each protrusion element of the plurality of protrusion elements, comprises a recess on the top surface of the protrusion element.

25. The method of claim 21, wherein the opening, of each protrusion element of the plurality of protrusion elements, comprises a recess at or near an edge of the protrusion element.

26. The method of claim 21, wherein the plurality of ball members of the one of the plurality of slots comprise silicon nitride, silicon carbide, zinc oxide, aluminum oxide, and/or quartz.
